(19) United States
(12) Patent Application Publication
(10) Pub. No.: US 2014/0360561 A1
(43) Pub. Date: Dec. 11, 2014

(54) FULLY REDUNDANT PHOTOVOLTAIC ARRAY

(71) Applicant: TENKSOLAR, INC., Minneapolis, MN (US)

(72) Inventors: Dallas W. Meyer, Prior Lake, MN (US); Lowell J. Berg, Eden Prairie, MN (US); Joel Cannon, Minneapolis, MN (US); Shady Gross, Bloomington, MN (US); Lance E. Stover, Eden Prairie, MN (US)

(21) Appl. No.: 14/465,392

(22) Filed: Aug. 21, 2014

Related U.S. Application Data
(63) Continuation-in-part of application No. 13/957,227, filed on Aug. 1, 2013.
Application No. 13/957,227 is a continuation-in-part of application No. 14/053,482, filed on Oct. 14, 2013.
Application No. 14/053,482 is a division of application No. 12/815,913, filed on Jun. 15, 2010, now Pat. No. 8,563,847.
Application No. 12/815,913 is a continuation-in-part of application No. 13/664,885, filed on Oct. 31, 2012.
(60) Provisional application No. 61/769,525, filed on Feb. 26, 2013.
(60) Provisional application No. 61/832,667, filed on Jun. 7, 2013.
(60) Provisional application No. 61/553,822, filed on Oct. 31, 2011.
(60) Provisional application No. 61/620,566, filed on Apr. 5, 2012.
(60) Provisional application No. 61/694,548, filed on Aug. 29, 2012.
(60) Provisional application No. 61/699,701, filed on Sep. 11, 2012.
(60) Provisional application No. 61/868,564, filed on Aug. 21, 2013.
(60) Provisional application No. 61/890,780, filed on Oct. 14, 2013.
(60) Provisional application No. 61/890,776, filed on Oct. 14, 2013.
(60) Provisional application No. 61/890,761, filed on Oct. 14, 2013.
(60) Provisional application No. 61/900,392, filed on Nov. 5, 2013.
(60) Provisional application No. 61/900,389, filed on Nov. 5, 2013.
(60) Provisional application No. 61/903,511, filed on Nov. 13, 2013.
(60) Provisional application No. 61/921,998, filed on Dec. 30, 2013.
(60) Provisional application No. 61/930,894, filed on Jan. 23, 2014.

(51) Int. Cl. H01L 31/042; H01L 31/05

(52) U.S. Cl. CPC H01L 31/0428; H01L 31/0424; H01L 31/0422; H01L 31/05
USPC 136/251; 136/244

(57) ABSTRACT

In an embodiment, a photovoltaic (PV) system includes a direct current (DC) bus, multiple PV modules and multiple inverter units. The PV modules are electrically coupled in parallel to the DC bus. The inverter units have DC inputs electrically coupled in parallel to the DC bus and have alternating current (AC) outputs electrically coupled to an AC grid.

### CROSS-REFERENCE TO RELATED APPLICATIONS

This application:

is a continuation-in-part of U.S. patent application Ser. No. 13/957,227, filed Aug. 1, 2013, which claims the benefit of and priority to U.S. Provisional Application No. 61/769,525, filed Feb. 26, 2013 and U.S. Provisional Application No. 61/832,667, filed Jun. 7, 2013;

is a continuation-in-part of U.S. patent application Ser. No. 14/053,482, filed Oct. 14, 2013, which is a divisional of U.S. patent application Ser. No. 12/815,913, filed Jun. 15, 2010;

is a continuation-in-part of U.S. patent application Ser. No. 13/664,885, filed Oct. 31, 2012, which claims the benefit of and priority to U.S. Provisional Application No. 61/553,822, filed Oct. 31, 2011; U.S. Provisional Application No. 61/620,566, filed Apr. 5, 2012; U.S. Provisional Application No. 61/694,548, filed Aug. 29, 2012; and U.S. Provisional Application No. 61/699,701, filed Sep. 11, 2012; and

claims the benefit of and priority to:

U.S. Provisional Application No. 61/868,564, filed Aug. 21, 2013;

U.S. Provisional Application No. 61/890,780, filed Oct. 14, 2013;

U.S. Provisional Application No. 61/890,776, filed Oct. 14, 2013;

U.S. Provisional Application No. 61/890,761, filed Oct. 14, 2013;

U.S. Provisional Application No. 61/900,392, filed Nov. 5, 2013;

U.S. Provisional Application No. 61/900,389, filed Nov. 5, 2013;

U.S. Provisional Application No. 61/903,511, filed Nov. 13, 2013;

U.S. Provisional Application No. 61/921,998, filed Dec. 30, 2013; and

U.S. Provisional Application No. 61/930,894, filed Jan. 23, 2014.

The foregoing applications are incorporated herein by reference in their entireties.

### FIELD

Example embodiments described herein relate to fully redundant photovoltaic (PV) arrays or systems.

### BACKGROUND

Unless otherwise indicated herein, the materials described herein are not prior art to the claims in the present application and are not admitted to be prior art by inclusion in this section.

In some photovoltaic PV solar arrays, serially interconnected solar modules are strung together to increase the voltage from module-to-module, usually limited to 600 volts direct current (VDC) in North America and 1000 VDC in Europe (480 VDC and 800 VDC with required safety margin). Such solar arrays are described as having a string topology. Large numbers of these module strings are often connected in parallel to a large central inverter. Imbalances in individual cells or panels where bypass diodes are triggered cause large changes in the peak power point for each string, requiring the need for stringent cell matching in the factory and requiring very uniform illumination, temperature, and other conditions when deployed.

Scaled down inverters termed “microinverters” have been introduced where the inverter is directly attached to each module and the AC output is wired in parallel, offering the ability to tolerate variation from module-to-module. DC optimizers have also been introduced for attachment at the module, to allow an improvement in string balancing between panels to reduce the inherent mismatch losses between panels.

There are a number of issues that exist in such alternate electrical topologies (e.g., topologies that use microinverters and/or DC optimizers) as well as with the string topology described above. The issues include at least the single-point-of-failure nature of such topologies. For example in the string topology, failure of any component in a string, including PV cells and PV cell illumination, PV cell connectors, PV module wiring, combiner boxes, inverters, etc. results in an immediate failure and requires field service to repair and restart the lost PV solar array portion or in many cases the entire PV solar array. In topologies that include microinverters and/or DC optimizers, the microinverters and/or DC optimizers help to minimize interdependencies of the string components, but are often limited in their operating range and introduce a host of additional electrical components with their own single-point-of-failure dependencies and field service requirements.

The subject matter claimed herein is not limited to embodiments that solve any disadvantages or that operate only in environments such as those described above. Rather, this background is only provided to illustrate one exemplary technology area where some embodiments described herein may be practiced.

### SUMMARY

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Some example embodiments described herein generally relate to fully redundant PV systems or arrays. Some embodiments may not include single-point-of-failure dependencies within the entire PV system. Alternately or additionally, failure of components within the PV systems described herein may be tolerated without significant performance degradation and field repairs to the failed components may be managed on extended and planned maintenance schedules.

In an example embodiment, a PV system includes a DC bus, multiple PV modules, and multiple inverter units. The PV modules are electrically coupled in parallel to the DC bus. Each of the PV modules includes one or more DC-to-DC power conversion circuits. Each of the PV modules is configured to independently control a composite electrical impedance of the corresponding one or more DC-to-DC power conversion circuits to operate at maximum peak power in response to the corresponding PV module detecting that a value of a DC bus voltage on the DC bus is between a first threshold value and a second threshold value greater than the first threshold value. Each of the PV modules is also configured to independently transition from operation at maximum peak power to a constant voltage mode in response to the corresponding PV module detecting that the value of the DC bus voltage is greater than the second threshold value. The inverter units have DC inputs electrically coupled in parallel to the DC bus and have alternating current (AC) outputs electrically coupled to an AC grid. Each of the inverter units has a DC voltage setpoint that has a different value than DC voltage setpoints of at least some of the other inverter units. Each of the inverter units is configured to independently begin converting DC power on the DC bus to AC power output to the AC grid in response to the corresponding inverter unit detecting that the value of the DC bus voltage is greater than or equal to the corresponding DC voltage setpoint of the corresponding inverter unit.

In another example embodiment, a PV system includes a DC bus, multiple PV modules and multiple inverter units. The PV modules are electrically coupled in parallel to the DC bus. The inverter units have DC inputs electrically coupled in parallel to the DC bus and have AC outputs electrically coupled to an AC grid.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIGS. 1A-1C illustrate various example PV systems;

FIG. 2 is a perspective view of an example of the PV systems of FIGS. 1A-1C;

FIG. 3 conceptually illustrates DC bus voltage levels on a DC bus of a PV system of FIGS. 1A-2 and a resulting PV system response;

FIGS. 4A and 4B illustrate curves that represent DC bus voltage as a function of available power level for the PV system of FIG. 1B or 1C under different conditions;

FIG. 5 is a block diagram of an embodiment of an inverter unit of FIGS. 1A-2;

FIGS. 6A-6C illustrate various views of an example common housing unit within which multiple inverter units may be located;

FIGS. 7A and 7B include various views of a PV module of FIGS. 1A-2;

FIG. 8 is a schematic diagram of an embodiment of a converter of FIGS. 1A-1C;

FIG. 9 is a perspective view of an elongate support and inverter units of FIGS. 1A-1C;

FIGS. 10A and 10B include various views of the elongate support of FIG. 9; and

FIG. 11 is a perspective view of a portion of the PV system of FIG. 2.

### DETAILED DESCRIPTION OF SOME EXAMPLE EMBODIMENTS

Embodiments described herein include PV systems with a DC bus, multiple PV modules and multiple inverter units. The PV modules are electrically coupled in parallel to the DC bus. The inverter units have DC inputs electrically coupled in parallel to the DC bus and have AC outputs electrically coupled to an AC grid.

Each PV module includes multiple PV cells electrically coupled in a mesh topology including both serial and parallel electrical connections between the PV cells, as described in more detail below. A continuous area conductive backsheet provides a current return path for current generated by the PV cells, the continuous area backsheet being electrically coupled between a first row of PV cells and a last row of PV cells where all other row of PV cells in the PV module are electrically coupled to the backsheet only through connections that include either the first or last row of PV cells. Each PV module includes a power conversion device with multiple DC-to-DC power conversion circuits electrically coupled between the last row of PV cells and the backsheet. The DC-to-DC power conversion circuits have outputs electrically coupled to a common internal DC bus that is electrically coupled to two bus connectors of the PV module. The electrical topology of the PV module allows current generated by any PV cell to flow to any DC-to-DC power conversion circuit such that failure of any particular PV cell, DC-to-DC power conversion circuit, or interconnection will not significantly reduce output of the PV module. In addition, the illumination between PV cells may vary without creating a cell-to-cell constraint (or bottleneck) as in a serial string of PV modules. Bypass diodes are not required anywhere in the individual PV modules or the PV system and in some implementations are omitted altogether from individual PV modules and/or the PV system as a whole.

The bus connectors of each PV module are connected to an external DC bus (hereinafter the “DC bus”) that is common to all of the PV modules in the PV system or to at least two or more PV modules in the PV system. The PV modules may be electrically connected in parallel to the DC bus. The bus connectors of the PV modules that electrically connect the PV modules to the DC bus may be utility grade interconnections and the DC bus may be continuous and uninterrupted from one PV module to the next to eliminate any dependency of any one connection upon another. As a result, failure of the connection of one PV module to the DC bus will not impact the connection of any of the other PV modules to the DC bus.

The PV system additionally includes multiple inverter units with DC inputs electrically coupled in parallel to the DC bus and AC outputs electrically coupled to the AC grid. The inverter units may include single-phase inverters, multi-phase inverters, or a combination of both single-phase inverters and multi-phase inverters.

A voltage on the DC bus, which voltage is referred to as the DC bus voltage, may be controlled by the inverter units and the PV modules without any communication (e.g., another potential failure point) therebetween. In these and other implementations, rather than trying to implement maximum power point tracking (MPPT) in each inverter unit, each inverter unit is set to maintain a fixed voltage value on the DC bus. The fixed voltage value is referred to as the DC voltage setpoint of the inverter unit. If the DC bus voltage is at or above the value of the DC voltage setpoint of an inverter unit, the inverter unit will pull energy from the DC bus and deliver it to the AC grid. After an individual inverter unit reaches its maximum AC power output (assuming sufficient illumination is present), the DC bus voltage will rise and another inverter unit with a higher value DC voltage setpoint will begin operating. In these and other implementations, the value of the DC voltage setpoint of each inverter unit may be different than the value of the DC voltage setpoint of at least some other inverter units. As such, each inverter unit may only operate when needed. In some implementations, the values of the DC voltage setpoints of the inverter units may be changed, e.g., daily, for wear-leveling across the inverter units. Alternately or additionally, the values of the DC voltage setpoints may be distributed in a voltage ladder, with a difference, or step size, between different and adjacent values being equal to about 0.2 volts or some other suitable step size. In some implementations, and as described in more detail below, each inverter unit may include multiple DC-to-DC converter circuits at its input that each have different DC-to-DC voltage setpoints such that additional granularity may be achieved by randomly selecting all available DC-to-DC voltage setpoints.

If an inverter unit fails, the other inverter units may continue to operate normally, with the only impact being the lost incremental inversion capacity from the failed inverter unit. All PV modules can still deliver energy to the AC grid through the non-failed inverter units. If the cumulative inversion capacity of the non-failed inverter units is exceeded, the DC bus voltage rises and some portion of the PV modules will transition to a constant voltage mode to self-limit the DC bus voltage and maintain a constant power operation at the sum of the peak output of the inverter units.

The PV modules may monitor operation of the PV system. If they detect that they are not connected to a live electrical circuit through the inverter units, the PV modules may output zero voltage and current. Alternately or additionally, the PV modules may communicate their operating and production status digitally through a front-side light emitting diode (LED) and/or through power line carrier (PLC) communication.

An energy storage device such as a battery may be included in some implementations of the PV system. The energy storage device may be electrically coupled directly to the DC bus since the PV modules may limit the DC bus voltage to a relatively low voltage that will not damage the energy storage device. The inverter units may control the PV system using a pre-programmed voltage ladder, external commands that define how much energy is allowed to flow from the PV system at any point in time, a combination of the two, or other suitable method(s). Any energy on the DC bus that does not flow through the inerter units to the AC grid may be stored in the energy storage device, which may cause a voltage of the energy storage device to rise. When the voltage of the energy storage device, and thus of the DC bus, reaches a threshold value as detected by one or more of the PV modules, the PV modules may cease output of energy to the DC bus, e.g., without the need for a diversion controller.

Reference will now be made to the drawings to describe various aspects of example embodiments of the invention. It is to be understood that the drawings are diagrammatic and schematic representations of such example embodiments, and are not limiting of the present invention, nor are they necessarily drawn to scale.

### I. PV System

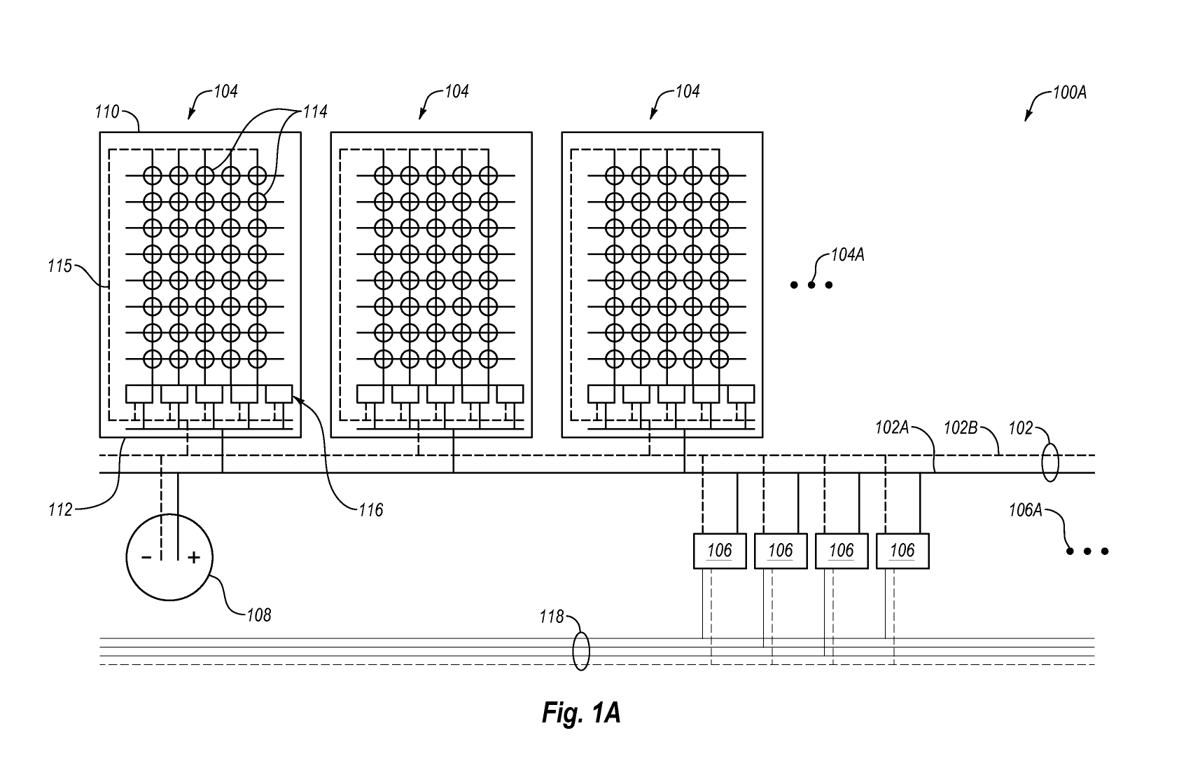

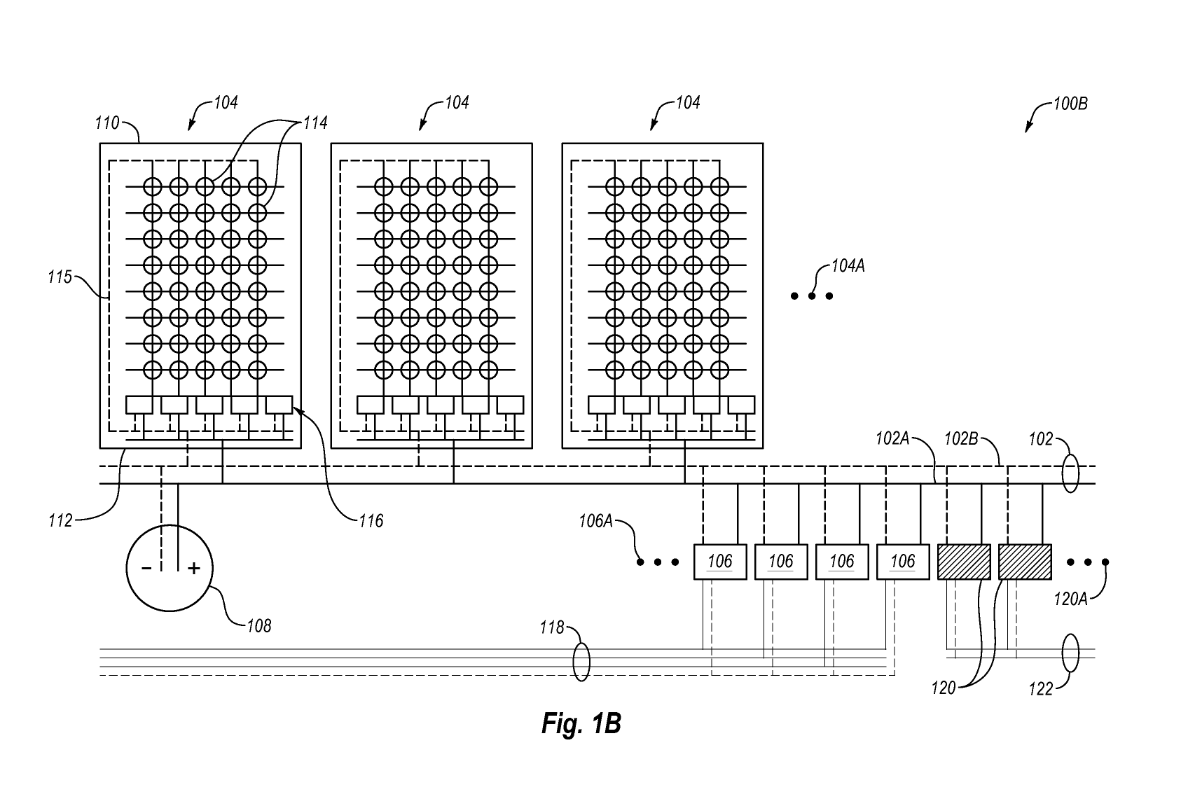

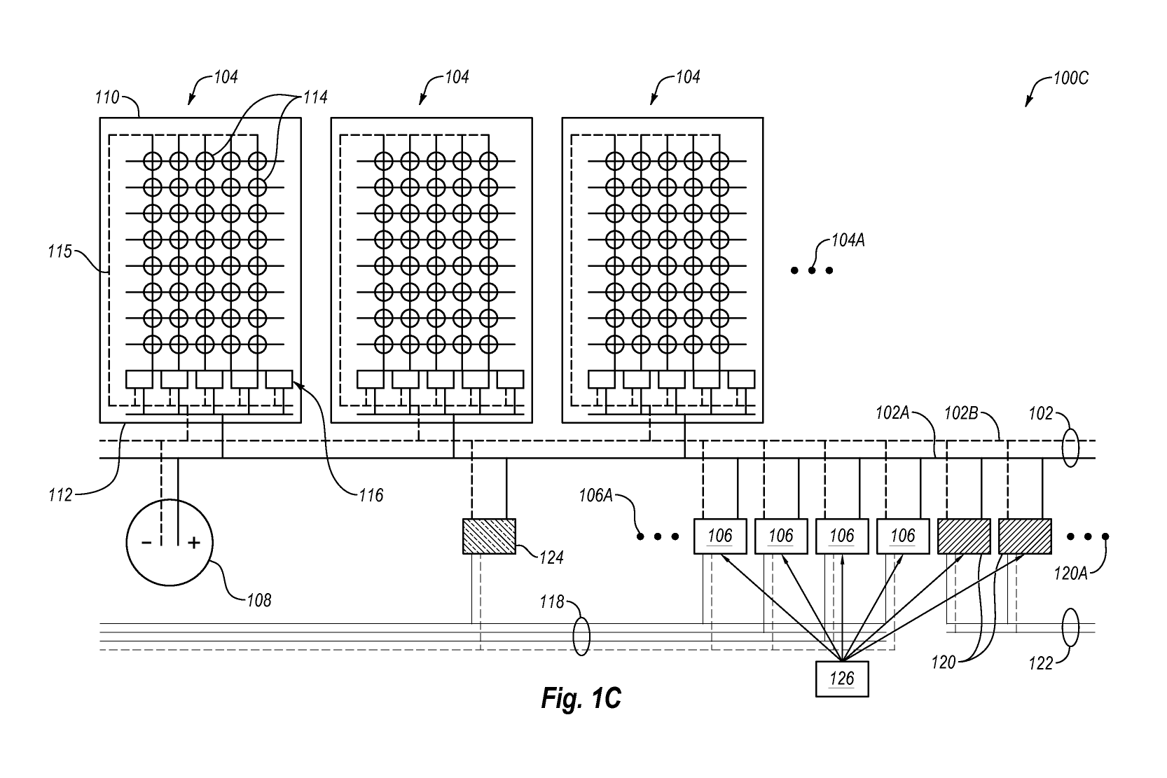

FIG. 1A illustrates an example PV system 100A, arranged in accordance with at least some embodiments described herein. The PV system 100A includes a DC bus 102, also referred to as a module-to-module bus, multiple PV modules or panels (hereinafter “modules”) 104, and multiple inverter units 106. Optionally, the PV system 100A additionally includes one or more energy storage devices 108.

While three PV modules 104 are illustrated in FIG. 1A, more generally the PV system 100A may include two or more PV modules 104, as denoted by ellipses 104A. Analogously, while four inverter units 106 are illustrated in FIG. 1A, more generally the PV system 100A may include two or more inverter units 106, as denoted by ellipses 106A.

An example configuration of each of the PV modules 104 will now be described. Although the specific aspects and features of the example configuration described herein are only called out in one of the PV modules 104 of FIG. 1A, it is understood that each of the PV modules 104 may be similarly configured.

As illustrated in FIG. 1A, each of the PV modules 104 defines a first end 110 and a second end 112. Each of the PV modules 104 includes multiple PV cells 114 (only some of which are labeled for simplicity) electrically coupled together in a mesh topology such that energy, e.g., PV current, generated by each PV cell 114 has multiple paths through the PV cells 114 toward the second end 112. In some embodiments, the mesh topology of the PV cells 114 is achieved by arranging the PV cells 114 in rows where the rows are electrically coupled in series and the PV cells 114 in each row are electrically coupled in parallel.

In some PV modules, the PV cells are electrically coupled in series such that an under-illuminated or poorly-performing or otherwise “blocked” PV cell limits the entire series. In embodiments described herein, however, because each PV cell 114 has multiple paths to the second end 112, when a PV cell 114 in one of the paths is blocked, energy produced by PV cells 114 upstream (e.g., nearer the first end 110) of the blocked PV cell 114 can flow around the blocked PV cell 114 through one of the other available paths.

Each of the PV modules 104 further includes a continuous area conductive backsheet 115 schematically illustrated in FIG. 1A by a dashed line. The backsheet 115 provides a current return path from the last row of PV cells 114 at the second end 112 to the first row of PV cells 114 at the first end 110. The intermediate rows of PV cells 114, e.g., the rows of PV cells 114 between the first row and the last row, may be electrically connected to the backsheet 115 only through connections that individually include either the first row or the last row, as illustrated in FIG. 1A.

Each of the PV modules 104 additionally includes one or more DC-to-DC power conversion circuits (hereinafter “converters”) 116 electrically coupled to the PV cells 114 at the second end 112 such that energy generated by each PV cell 114 is receivable at any of the converters 116. As such, if one of the converters 116 fails, the energy that was previously flowing to that converter 116 can flow to a different one of the converters 116. In general, the converters 116 are configured to convert relatively high-current, low-voltage energy collectively generated by the PV cells 114 to a lower current and higher voltage. Accordingly, each of the converters 116 may include, for example, a boost converter, a buck-boost converter, a SEPIC converter, a tuk converter, or the like or any combination thereof.

The PV modules 104 are electrically coupled to the DC bus 102 in parallel. Analogously, the inverter units 106 have DC inputs electrically coupled to the DC bus 102 in parallel. As such, energy generated by each PV module 104 is receivable at any of the inverter units 106 independent of any other of the PV modules 104 or inverter units 106.

The DC bus 102 collects the DC output of the PV modules 104. In the illustrated embodiment, the DC bus 102 includes a positive lead 102A and a negative lead 102B. Each of the positive lead 102A and the negative lead 102B may include a continuous and uninterrupted elongate electrical conductor to which each of the PV modules 104 is electrically coupled. In some implementations, each of the positive lead 102A and the negative lead 102B includes a #2 AWG aluminum wire or other continuous conductor having a cross-sectional area (e.g., normal to a length of the conductor) of at least 33 millimeters squared (mm²).

Because the leads 102A, 102B of the DC bus 102 include continuous conductors and the PV modules 104 are connected in parallel to the DC bus 102, a failure of any one of the PV modules 104 will not affect an ability of any of the other PV modules 104 to output energy onto the DC bus 102 to the inverter units 106 and/or to the energy storage device 108. Accordingly, the PV system 100A can continue producing energy even in the event some of the PV modules 104 fail such that immediate maintenance on the failed PV modules 104 is not required to keep the PV system 100A running, as is the case with some PV systems where the PV modules or panels are connected in series.

The inverter units 106 are electrically coupled to the DC bus 102 such that energy generated by each of the PV modules 104 is receivable at any of the inverter units 106. The inverter units 106 each have a DC side, the DC sides of the inverter units 106 being electrically coupled in parallel to the DC bus 102. In general, the inverter units 106 are configured to convert DC power on the DC bus 102 to alternating current (AC) power that is output to an AC grid 118 to which AC sides of the inverter units 106 are coupled.

The AC grid 118 may include a multi-phase AC power grid, such as a three-phase AC grid. The inverter units 106 may be electrically coupled to any or all of the phases of the power grid 118. In the illustrated embodiment, each of the inverter units 106 is a single-phase inverter unit and is electrically coupled to a different one of the three phases of the power grid 118 through, for example, a Wye or a Delta connection. Each of the inverter units 106 may optionally be electrically coupled to a common neutral lead of the AC grid 118. In other embodiments, one or more of the inverter units 106 may include a multi-phase inverter unit that is electrically coupled to two or more phases of the AC grid 118.

The energy storage device 108 may be coupled in parallel with the PV modules 104 to the DC bus 102.

The PV system 100A may have an operating voltage range (e.g., voltage swing). In implementations in which an energy storage device is omitted from the PV system 100A, a lower threshold value of the operating voltage range may be equal to a lowest value DC voltage setpoint of the inverter units 106 and an upper threshold value of the operating voltage range may be equal to an upper voltage at which the PV modules 106 transition to constant voltage mode. For example, the lower threshold value may be 51 volts and the upper threshold value may be 57 volts in some implementations such that the operating voltage range is 51-57 volts.

Alternately or additionally, in implementations that include the energy storage device 108, the operating voltage range may be determined relative to a state of charge of the energy storage device 108. The lower threshold value may be equal to a voltage of the energy storage device 108 at a minimum target state of charge of the energy storage device 108 that is sufficiently high to avoid cycling issues and the upper threshold value may be equal to a voltage of the energy storage device 108 at a maximum target state of charge of the energy storage device 108, which maximum target state of charge may be less than 100% to maximize cycle life. For example, the lower threshold value may be 48 volts and the upper threshold value may be 57 volts in some implementations such that the operating voltage range is 48-57 volts. The voltage of the energy storage device 108 at the minimum target state of charge may be referred to as the lower charge threshold value and the voltage of the energy storage device 108 at the maximum target state of charge may be referred to as the upper charge threshold value.

FIG. 1B illustrates another example PV system 100B, arranged in accordance with at least some embodiments described herein. The PV system 100B of FIG. 1B includes many of the same components as the PV system 100A of FIG. 1A and a description of the common components will not be repeated. The PV system 100B of FIG. 1B additionally includes one or more auxiliary inverter units 120 that have DC inputs electrically coupled in parallel with DC inputs of the inverter units 106 and that have AC outputs electrically coupled to an auxiliary AC circuit 122 that is isolated from the AC grid 118. While two auxiliary inverter units 120 are illustrated in FIG. 1A, more generally the PV system 100B may include one or more auxiliary inverter units 120, as denoted by ellipses 120A.

The auxiliary AC circuit 122 may be electrically coupled to one or more output nodes (e.g., one or more power outlets) within a residence, commercial site, or other location that includes other output nodes electrically coupled to the AC grid 118. When the PV modules 104 are outputting DC power to the DC bus 102, a value of the DC bus voltage is greater than or equal to a value of a DC voltage setpoint of at least one of the auxiliary inverter units 120, and there is a load connected to the auxiliary AC circuit 122, the corresponding auxiliary inverter unit 120 may convert DC power on the DC bus 102 to AC power on the auxiliary AC circuit 122. Under the foregoing circumstances, the PV system 100B may provide power through the auxiliary AC circuit 122 even when the AC grid 118 is down and optionally without the added cost of an energy storage device. In contrast, in other PV systems connected to the AC grid, energy generated by the PV modules cannot be used when the AC grid is down without a relatively expensive hybrid inverter that includes an automatic transfer switch (ATS) to switch between output to the AC grid or output to an auxiliary system. Alternately or additionally, where the energy storage device 108 is included in the PV system 100B and provided the DC voltage setpoint of at least one of the auxiliary units 120 is set appropriately, energy stored in the energy storage device 108 may be exported to the auxiliary AC circuit 122 (when there is a connected load) even when the PV modules 104 are not generating energy.

In some implementations, each of the auxiliary inverter units 120 has a DC voltage setpoint with a value that is lower than any DC voltage setpoint values of the inverter units 106 such that energy is delivered to the auxiliary AC circuit 122 before (or with higher priority than) energy is delivered to the AC grid 118. In particular, by having lower DC voltage setpoint values, the auxiliary inverter units 120 may begin pulling power from the DC bus 102 before the inverter units 106 begin pulling power from the DC bus 102 as the PV system 100B powers up (e.g., in the morning) and may continue pulling power from the DC bus 102 after the inverter units 106 have stopped pulling power from the DC bus 102 as the PV system 100B powers down (e.g., in the evening).

In other implementations, each of the auxiliary inverter units 120 has a DC voltage setpoint with a value that is higher than any DC voltage setpoint values of the inverter units 106 such that energy is delivered to the AC grid 118 before (or with higher priority than) energy is delivered to the auxiliary AC circuit 122. In particular, by having higher DC voltage setpoint values, the auxiliary inverter units 120 may begin pulling power from the DC bus 102 after the inverter units 106 begin pulling power from the DC bus 102 as the PV system 100B powers up (e.g., in the morning) and may stop pulling power from the DC bus 102 before the inverter units 106 have stopped pulling power from the DC bus 102 as the PV system 100B powers down (e.g., in the evening).

Alternately or additionally, one or more of the auxiliary inverter units 120 may have a DC voltage setpoint with a value that is lower than any DC voltage setpoint values of the inverter units 106 while one or more other auxiliary inverter units 120 may have a DC voltage setpoint with a value that is higher than any of the DC voltage setpoint values of the inverter units 106.

In some implementations, the energy storage device 108 includes a capacitor or other suitable energy storage device. In these and other implementations, the energy storage device 108 may be configured to support inrush current requirements of loads electrically coupled to the auxiliary AC circuit 122.

The inverter units 106 and/or the auxiliary inverter units 120 may include microinverters that are convection cooled off their surface with no moving parts, or other suitable inverters. In more detail, the inverter units 106 and/or the auxiliary inverter units 120 may include solid-state, fully enclosed and potted elements that are convection cooled and that lack moving parts, filters, conditioning units, etc. and that are galvanically isolated from the AC grid 118. The inverter units 106 and/or the auxiliary inverter units 120 may be configured to individually convert a relatively small amount of power (e.g., 500-1000 watts) such that they may be fabricated with low-cost, high-speed surface mount components and using high-reliability packaging, process and assembly methods developed in other high-volume technology industries.

FIG. 1C illustrates another example PV system 100C, arranged in accordance with at least some embodiments described herein. The PV system 100C of FIG. 1C includes many of the same components as the PV systems 100A and 100B of FIGS. 1A and 1B and a description of the common components will not be repeated. Compared to the PV system 100B of FIG. 1B, the PV system 100C of FIG. 1C additionally includes one or more AC-to-DC converters 124 connected between the AC grid 118 and the DC bus 102. The AC-to-DC converter 124 may be configured to convert AC energy from the AC grid 118 to DC energy on the DC bus 102. The AC-to-DC converter 124 may pull energy from the AC grid 118 to the DC bus 102 to recharge the energy storage device 108 (when the energy storage device 108 is included in the PV system 100C) and/or to power the auxiliary inverter units 120 so that power is provided to the auxiliary AC circuit 122.

FIG. 1C additionally illustrates a central control device 126 that may optionally be included in the PV system 100C of FIG. 1C, and/or in the PV systems 100A and 100B of FIGS. 1A and 1B. The central control device 126 may be communicatively coupled to the inverter units 106 and/or the auxiliary inverter units 120 (collectively “inverter units 106/120”) and may be configured to coordinate and/or control operation of the inverter units 106/120. The central control device 126 may include one of the inverter units 106/120 implemented as a master inverter unit with the others implemented as slave inverter units to the master inverter unit. Alternately or additionally, the central control device 126 may include a communication-enabled computing device that can engage in at least one-way communication with the inverter units 106/120. The central control device 126 may coordinate and/or control operation of the inverter units 106/120 by, e.g., enabling or disabling operation of particular ones or groups of the inverter units 106/120, setting and/or changing values of voltage setpoints of the inverter units 106/120, limiting power output (e.g., through AC curtailment) of particular ones or groups of the inverter units 106/120, or other suitable processes or methods.

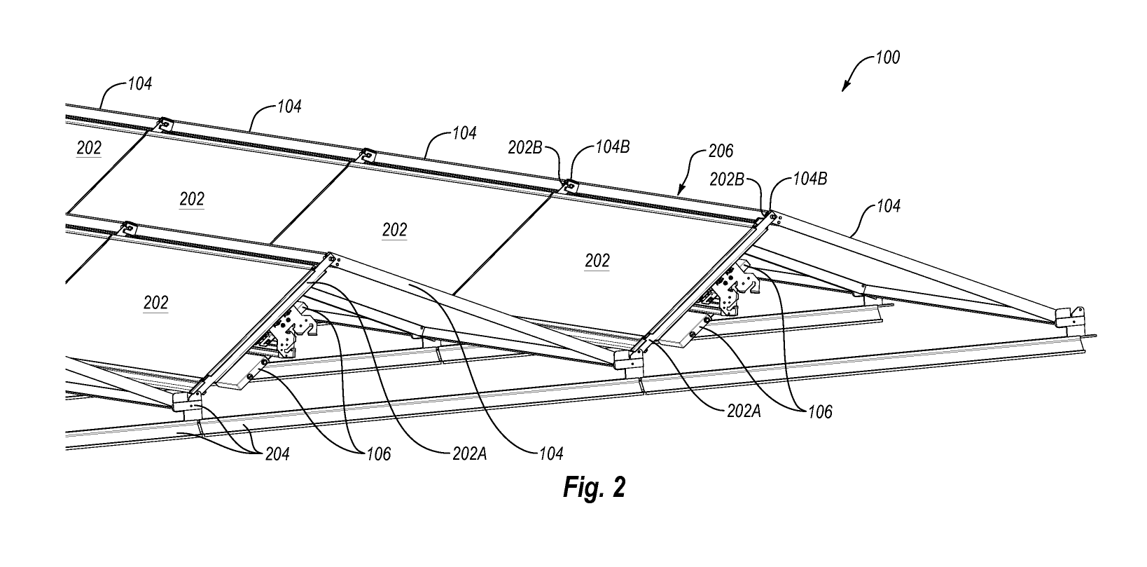

FIG. 2 is a perspective view of an example of the PV systems 100 of FIGS. 1A-1C, arranged in accordance with at least some embodiments described herein. FIG. 2 illustrates the PV modules 104 and inverter units 106 of FIGS. 1A-1C as well as multiple reflectors 202 and a racking assembly 204 (only a portion of which is labeled in FIG. 2) that mechanically interconnects the PV modules 104 and the reflectors 202 together. Additional details regarding example implementations of the racking assembly are disclosed in U.S. patent application Ser. No. 13/957,227. Although not visible in the perspective view of FIG. 2, one or more of the other components described with respect to FIGS. 1A-1C may be included in the PV system 100 of FIG. 2, such as the DC bus 102, the energy storage device 108, the auxiliary inverter circuits 120, the failover inverter circuits, and/or the central control device 126.

The inverter units 106 may be mounted behind one or more of the reflectors 202. For instance, as illustrated in FIG. 2, the inverter units 106 are mounted behind two of the reflectors 202. In some implementations, the inverter units 106 may be mechanically coupled to one or more extruded rods or other elongate supports (not shown in FIG. 2) that are mechanically coupled to a frame 202A of the corresponding reflector 202 to mount the inverter units 106 behind the corresponding reflector 202.

In some implementations, the PV modules 104 and the reflectors 202 are arranged in rows of PV modules 104 and rows of reflectors 202, with the rows of reflectors 202 generally being interposed between the rows of PV modules 104. In general, PV systems 100 according to the described embodiments may include any number of PV modules 104 and reflectors 202 arranged in any number of rows. Further, there may be more rows of PV modules 104 than rows of reflectors 202, or vice versa.

Similar to the reflectors 202, the PV modules 106 may each include a frame 104 (not labeled). Both the frame 202A of each reflector 202 and the frame of each PV module 106 may include frame extensions that extend from each of four corners of the corresponding frame. For example, the frame of each PV module 106 may include two upper frame extensions 104B (which are only labeled for one of the PV modules 106) and two lower frame extensions (not labeled). Similarly, the frame 202A of each reflector may include two upper frame extensions 202B (which are only labeled for one of the reflectors 202) and two lower frame extensions (not labeled). Each PV module 104 may be mechanically coupled to the corresponding reflector 202 behind it by coupling each of the two upper frame extensions 104B of the corresponding PV module 104 to the corresponding upper frame extensions 202B of the corresponding reflector 202.

As illustrated in FIG. 2, the two upper frame extensions 104B extend to a height above an upper edge 206 of the corresponding PV module 104. As a result, at least some of the upper frame extensions 104B of the PV modules 104 within at least some of the rows of PV modules 104 may cast shadows on one or more PV modules 104 within adjacent rows of PV modules 104 under at least some angles of incident illumination.

Each of the PV modules 104 may have a linear power response with respect to illumination area of the PV cells 114 (FIGS. 1A-1C) of the corresponding PV module 104. In PV modules 104 having a linear power response with respect to illumination area of the PV cells 114, any loss of incoming illumination on any PV cells 114 of the PV module 104 results in a linear decrease in power output of the PV module 104. More generally, in PV modules 104 having a linear power response, any change in illumination intensity across any PV cells 114 of the PV module 104 results in a linear change in power output of the PV module 104. Accordingly, partial shading due to the upper frame extensions 104B or other non-uniform illumination generally only reduces the power output of each PV module by the reduced output of the affected PV cells 114, rather than the affected PV cells 114 creating a bottleneck that limits the output of all of the PV cells 114 as occurs with PV cells that are only connected in series.

The reflectors 202 may generally be configured to reflect at least some illumination incident on the reflectors 202 onto the PV modules 104. Whereas the inverter units 106 may be mounted behind one or more of the reflectors 202, the reflected illumination may thereby be prevented from being incident on the inverter units 106, which may minimize ambient temperature of the inverter units 106. Alternately or additionally, locating the inverter units 106 beneath one or more of the reflectors 202 at least partially protects the inverter units 106 from precipitation and prolonged exposure to sunlight, which may extend the lifetime of the inverter units 106.

### II. Inverter Units

A. Inverter Unit Control and Operation

Referring to FIGS. 1A-1C, in some implementations, the inverter units 106 have different DC voltage setpoints distributed in a voltage ladder in which each inverter unit 106 has a DC voltage setpoint that has a different value than DC voltage setpoints of at least some of the other inverter units 106. The DC voltage setpoints of the inverter units 106 may be offset by 0.1-0.5 volts, or by less than 0.1 volts or more than 0.5 volts. In an example embodiment, one of the inverter units 106 has a DC voltage setpoint of 51.0 volts, another has a DC voltage setpoint of 51.2 volts, and so on in 0.2 volt increments (or step sizes) up to 52.0 volts, 53.0 volts, or some other value. Where the inverter units 106 have different DC voltage setpoints, power distribution from the DC bus 102 to the inverter units 106 is determined by the DC voltage setpoints. For example, the inverter unit 106 with the lowest DC voltage setpoint, such as 51.0 volts, will begin pulling power when the voltage on the DC bus 102 is 51.0 volts; if the voltage on the DC bus 102 rises to the next DC voltage setpoint, such as 51.2 volts, the inverter unit 106 with the next DC voltage setpoint will then begin pulling power, and so on.

There may be some overlap of the inverter units 106/120 powering on depending on line impedance and the step size. In more detail, and as described below, each inverter unit 106/120 may have a finite slope of DC voltage setpoint versus power on the DC bus 102 such that the value of the DC voltage setpoint of each inverter unit 106/120 rises before reaching saturation (e.g., full power output). For instance, the DC voltage setpoint versus power on the DC bus 102 for each of the inverter units 106/120 may have a finite slope of about 0.2 volts per 500 watts of power. More generally, the DC voltage setpoint versus power on the DC bus 102 for each of the inverter units 106/120 may have a finite slope defined as a change of its DC voltage setpoint from 0 watts to saturation. If the value of the finite slope is less than the step sizes of the voltage ladder, the inverter unit 106/120 with the next DC voltage setpoint value in the voltage ladder may power on before the inverter unit 106/120 with the previous DC voltage setpoint value in the voltage ladder reaches full saturation.

Alternately or additionally, the DC voltage setpoints of the inverter units 106 and/or AC curtailment of the inverter units 106 may be adjustable. In general, AC curtailment is a limiting feature on the AC output from the inverter unit 106. In these and other embodiments, the inverter units 106 may be communicatively coupled together and/or may be communicatively coupled to the central control device 126, e.g., via a modbus, a controller area network (CAN) bus, PLC communication, radio frequency (RF) communication, or other communication channel. The inverter units 106 may communicate with each other and/or the central control device 126 to coordinate control of inverter unit-specific settings such as the DC voltage setpoints of the inverter units 106, AC curtailment of the inverter units 106, or other settings.

By coupling each of the inverter units 106 to a different phase of the power grid 118 as illustrated in FIGS. 1A-1C, implementing different DC voltage setpoints for the inverter units 106 and/or implementing adjustable DC voltage setpoints for the inverter units 106, the PV system 100 may be operated in a variety of ways. For example, current may selectively flow from the inverter units 106 to different phases of the power grid 118, into the energy storage device 108 and/or from the energy storage device 108. As another example, current may flow from one or more phases of the power grid 118 to the DC bus 102 via the AC-to-DC converter 124 and may flow along the DC bus 102 with or without power generated by the PV modules 104 to one or more other phases of the power grid 118, to the energy storage device 108, and/or to the auxiliary inverter units 120. As another example, based on DC voltage setpoints of the inverter units 106, settings of the AC-to-DC converter 124, and/or a current state of charge of the energy storage device 108, current may flow into the energy storage device 108 from any or all phases of the power grid 118 or from the energy storage device 108 into any or all phases of the power grid 118.

Alternately or additionally, each of the inverter units 106 may be selectively disabled and enabled based on one or more enable/disable criteria. The enable/disable criteria may be static or adjustable. The enable/disable criteria may include voltage on the DC bus 102, time of day, or other criteria. For example, one or more of the inverter units 106 may be disabled every morning and/or evening when output of the PV modules 104 is expected to be relatively lower than at midday such that the remaining enabled inverter units 106 operate at a relatively higher efficiency or the PV system 100 performance is otherwise optimized.

Alternately or additionally, the inverter units 106/120 may be assigned new DC voltage setpoints at least once daily through an arbitration or master control process implemented by the inverter units 106/120 or by the central control device 126 based one or more setpoint criteria. The setpoint criteria may be static or adjustable. The setpoint criteria may include at least one of total power-on time of each inverter unit 106/120, a cumulative sum for each inverter unit 106/120 across multiple temperature ranges of power-on time of the corresponding inverter unit 106/120 while operating at a corresponding one of the temperature ranges multiplied by a temperature within the corresponding one of the temperature ranges, self-monitored efficiency of each inverter unit 106/120, current temperature of each inverter unit 106/120, and/or AC voltage output of each inverter unit 106/120. Alternately or additionally, the setpoint criteria may include a power-weighted temperature defined as (sum of power output multiplied by temperature of the inverter unit 106/120 at the power output across multiple power outputs) divided by (sum of power output across the multiple power outputs). In some implementations, inverter units 106/120 with less total power-on time, lower cumulative sums, higher efficiency, lower current temperature, higher AC voltage output, or lower power-weighted temperature may be assigned lower DC voltage setpoints.

Each of the inverter units 106/120 may be configured to independently begin converting DC power on the DC bus 102 to AC power output to the AC grid 118 in response to the corresponding inverter unit 106/120 detecting that the value of the DC bus voltage is greater than or equal to the corresponding DC voltage setpoint of the corresponding inverter unit 106/120. Alternately or additionally, each inverter unit 106/120 may be configured to pull DC power from the DC bus 102 in response to the corresponding inverter unit 106/120 detecting that the DC bus voltage on the DC bus 102 is greater than or equal to the corresponding DC voltage setpoint, all without considering total DC power on the DC bus or whether other inverter units 106/120 are pulling DC power from the DC bus 102. An amount of power converted by each of the inverter units 106/120 may depend on total DC power on the DC bus 102 and DC voltage setpoints of all the other inverter units 106/120.

In general, the PV systems 100A-100C (generically “PV system 100” or PV systems 100″) may operate during sequential periods during each of which the PV system 100 produces power and between which the PV system 100 does not produce power. The sequential periods of operation may each include a continuous period, such as a day or a portion of a day, in which the PV modules 104 of the PV system 100 receive sufficient illumination to produce power. Each sequential period may be terminated when there is insufficient illumination for the PV modules 104 to produce power, e.g., at night, or at some other time. Each of the inverter units 106/120 may include a DC voltage setpoint that is changed from operation period to operation period. Thus, for each inverter unit 106/120, the corresponding DC voltage setpoint may have a different value during one of the operation periods than during a subsequent one of the operation periods. During each of the operation periods, the DC voltage setpoint of each of the inverter units 106/120 may have a different value than DC voltage setpoints of at least some of the other inverter units 106/120.

The DC voltage setpoints may be changed at each inverter startup (e.g., start of each day or other operation period) and/or at some other time. For a given inverter unit 106 and/or auxiliary inverter unit 120, the value of the DC voltage setpoint may be changed to one of multiple possible discrete values according to a pre-programmed rotation or method or according to a random or pseudo-random DC setpoint adjustment algorithm or other suitable method or algorithm. The change of the DC voltage setpoints may result in wear-leveling of the inverter units 106/120. In particular, the inverter units 106/120 that have relatively low DC voltage setpoints one day, and that are therefore powered on for a longer duration during the day than those with relatively high DC voltage setpoints, may have a relatively high DC voltage setpoint the next day and may therefore be powered on for a relatively shorter duration during the next day than those with relatively low DC voltage setpoints. As a result, and over time, all inverter units 106/120 may generally be powered on for about the same amount of time, resulting in about the same amount of wear (e.g., “wear-leveling”) across all inverter units 106/120.

Implementations described herein may include a central control device, such as the central control device 126 of FIG. 1C. Alternately, the PV systems 100 may omit a central control device that coordinates or controls operation of the inverter units 106/120. In these and other embodiments, a flow of energy from the DC bus 102 to the AC grid 118 may be controlled by each of the inverter units 106/120 independently responding to a difference between the DC bus voltage and the corresponding DC voltage setpoint. For instance, each inverter unit 106/120 may be powered on to pull energy from the DC bus 102 to the AC grid 118 when the DC bus voltage is greater than or equal to the DC voltage setpoint of the inverter unit 106/120. Alternately or additionally, each inverter unit 106/120 may be powered off when the DC bus voltage is less than the DC voltage setpoint of the inverter unit 106/120.

In some implementations, each inverter unit 106/120 has a finites slope of DC voltage setpoint versus power on the DC bus 102 such that as power on the DC bus 102 increases, the corresponding DC voltage setpoint of each inverter unit 106/120 increases. For instance, the DC voltage setpoint versus power on the DC bus 102 for each of the inverter units 106/120 may have a finite slope of about 0.1-0.2 volts per 500 watts of power.

The inverter units 106/120 may generally operate more efficiently at higher power levels. In these and other implementations, values of the DC voltage setpoints of the inverter units 106/120 may be asymmetrically distributed across the inverter units 106/120. For example, the lowest value and potentially other relatively low values of the DC voltage setpoints may each be associated with a different single one of the inverter units 106/120, while relatively higher values of the DC voltage setpoints may each be associated with different sets of two or more of the inverter units 106/120. Accordingly, at relatively lower power levels where the inverter units 106/120 are relatively less efficient, a single inverter unit 106/120 may power on at a time as the power level on the DC bus 102 rises, whereas at relatively higher power levels where the inverter units 106/120 are relatively more efficient, multiple inverter units 106/120 may power on at a time (or at about the same time) that have the same DC voltage setpoint values.

As previously mentioned, a central control device, such as the central control device 126 of FIG. 1C, may be included in any of the PV systems 100, where the central control device 126 is configured to coordinate and/or control operation of the inverter units 106/120. Although the central control device 126 is only illustrated in FIG. 1C, it will be described in the context of FIGS. 1A-1C as it may be included in any of the PV systems 100A-100C.

In these and other implementations, each inverter unit 106/120 may be configured to turn on or off responsive to an enable signal or a disable signal received from the central control device 126. The central control device 126 may determine which inverter units 106/120 to enable and/or disable to optimize conversion efficiency of DC power to AC power of the PV system 100. Communication between the central control device 126 and the inverter units 106/120 may be one-way and solely from the central control device 126 to the inverter units 106/120. Alternately or additionally, a handshake or other communication from any of the inverter units 106/120 to the central control device 126 to confirm a response to the enable signal or disable signal may be omitted. Due at least in part to the granularity of the PV system 100, e.g., multiple inverter units 106/120 electrically coupled in parallel to the DC bus 102, the handshake or other communication to confirm a response can be omitted since a failure of some of the inverter units 106/120 to receive the enable signal or disable signal may not significantly impact performance of the PV system 100 as long as some of the inverter units 106/120 receive the enable signal or disable signal. The omission of a handshake or other communication to confirm a response may reduce communication time and a response time of the PV system 100 to respond to changing conditions in real-time.

The inverter units 106/120 may be divided into groups of two or more inverter units 106/120 where each group has a different group number that identifies the group. In some implementations, each group of inverter units 106/120 may be associated with a sub-array of PV modules 104. In particular, each of the inverter units 106/120 in one group may have DC inputs electrically coupled in parallel to a DC bus to which the PV modules 104 in the sub-array are coupled in parallel. Other groups of inverter units 106/120 and other sub-arrays of PV modules 104 may be similarly electrically coupled to other DC buses.

The group numbers may be assigned at any time, such as during assembly of the PV system 100. Each inverter unit 106/120 may additionally have an identification (ID) number that uniquely identifies the inverter unit 106/120 within a corresponding group. E.g., the group number and ID number of each inverter unit 106/120 may uniquely identify that inverter unit 106/120 within the PV system 100. In these and other implementations, the central control device 126 may broadcast enable or disable signals or other commands by group number, ID number, and/or other suitable identifier. For example, responsive to determining that turning off the inverter units 106/120 included in one or more groups will improve efficiency of the PV system 100, the central control device 126 may be configured to broadcast one or more corresponding group numbers. Each inverter unit 106/120 may be configured to turn off responsive to receiving a broadcast from the central control device 126 that includes the group number of the corresponding inverter unit and/or a disable signal. As described above, a handshake or other communication to confirm a response to the broadcast can be omitted.

Each inverter unit 106/120 that turns off responsive to receiving the broadcast that includes the group number of the corresponding inverter unit may be configured to turn on and resume operation after passage of a pre-programmed duration of time and without receiving a communication from the central control device 126 to turn on and resume operation. The pre-programmed duration of time may include, for example, 15 minutes.

In some implementations, each of the inverter units 106/120 has a DC voltage setpoint with a value that is less than the lower charge threshold value of the energy storage device 108. Accordingly, each of the inverter units 106/120 may be configured to export power from the energy storage device 108 via the DC bus 102 to the AC grid 118 or the auxiliary AC circuit 122 responsive to an enable signal from the central control device 126 and responsive to a voltage of the energy storage device 108 being greater than or equal to the corresponding DC voltage setpoint of the corresponding inverter unit 106/120.

As illustrated in FIGS. 1A-1C, each of the inverter units 106 is coupled to a different phase of the AC grid 118. In particular, a first set of one or more of the inverter units 106 is electrically coupled to a first phase of the AC grid 118, a second set of one or more of the inverter units 106 is electrically coupled to a second phase of the AC grid 118, and a third set of one or more of the inverter units 106 is electrically coupled to a third phase of the AC grid 118. In these and other implementations, the central control device 126 may be configured to selectively enable or disable each of the first set, the second set, or the third set of inverters 106 to phase balance. Phase balancing may include balancing the AC power output from the PV system 100 across all three phases independently of the AC grid 118. Alternately or additionally, phase balancing may include adjusting the AC power output of the PV system 100 actively to put more of the AC power output onto one phase than another based on, e.g., what a utility needs or based on measured voltage of each of the phases. For example, if the PV system 100 determines by measuring the voltage of each of the phases of the AC grid 118 that one of the phases is sagging, the PV system 100 may output more of the AC power output to the phase that is sagging.

In some implementations, each of the inverter units 106 may have different reactive power (VAR) settings than at least some other inverter units 106. For instance, one set of one or more of the inverter units 106 may have first VAR settings and another set of one or more of the inverter units 106 may have second VAR settings that are different than the first VAR settings. In these and other implementations, the central control device 126 may be configured to selectively enable or disable the various sets to adjust VAR of the PV system 100. The adjustment may be based on the local state of the AC grid 118. For instance, the VAR of the AC grid 118 local to the PV system 100 may be determined by the PV system 100 and the VAR of the PV system 100 may be adjusted to increase or decrease the VAR of the AC grid 118 local to the PV system 100.

Optionally, the PV system 100 may further include multiple failover inverter units (not illustrated) electrically coupled to the DC bus 102 and the AC grid 118 in the same manner as the inverter units 106. In particular, DC inputs of the failover inverter units may be electrically coupled in parallel to the DC bus 102 and AC outputs of the failover inverter units may be electrically coupled to the AC grid 118. The failover inverter units may be semi-permanently disabled, meaning they may be unable to power on whether or not values of their DC setpoints are less than or equal to the DC bus voltage. The central control device 126 may be configured to detect failed inverter units among the inverter units 106 and may be further configured to enable failover inverter units responsive to detecting the failed ones of the inverter units 106. The failover inverter units may be enabled by sending an enable signal or other suitable signal from the central control device 126.

Alternately or additionally, the central control device 126 may be configured to set DC voltage setpoints of the inverter units 106/120 and/or to enable and/or disable operation of the inverter units 106/120. For example, the central control device 126 may set DC voltage setpoints daily, at startup, or at other times and/or may enable and/or disable inverter units 106/120 as needed to optimize performance of the PV system 100. The central control device 126 may communicate with the inverter units 106/120 through at least one of PLC communication or RF communication or other suitable communication to communicate DC voltage setpoints, enable signals, and/or disable signals to the inverter units 106/120.

In implementations that include the central control device 126 communicatively coupled to the inverter units 106/120 and/or in which the inverter units 106/120 are communicatively coupled to each other, the central control device 126, communication between the central control device 126 and the inverters 106/120, and/or communication of the inverter units 106/120 with each other may fail. Responsive to such failures, each of the inverter units 106/120 may be configured to default to a DC voltage setpoint selection to continue operation of the PV system 100 despite the failure. For example, each of the inverter units 106/120 may be configured to independently set its own DC voltage setpoint and/or operate independently of the other inverter units 106/120 based on the DC bus voltage and based on the DC voltage setpoint of the corresponding inverter unit 106/120.

According to some implementations, a DC voltage setpoint of each of the inverter units 106/120 may be adjusted based on temperature of the corresponding inverter unit 106/120 to adjust the thermal profile across the inverter units 106/120. Generally, adjusting the DC voltage setpoint of each of the inverter units 106/120 may include increasing a value of the DC voltage setpoint with increasing temperature of the corresponding inverter unit 106/120 and/or decreasing the value of the DC voltage setpoint with decreasing temperature of the corresponding inverter unit 106/120. For example, the value of the DC voltage setpoint of the corresponding inverter unit 106/120 may be increased responsive to a temperature of the corresponding inverter unit 106/120 increasing by a threshold amount or being at or a above a first temperature threshold value. Alternately or additionally, the value of the DC voltage setpoint of the corresponding inverter unit 106/120 may be decreased responsive to the temperature of the corresponding inverter unit 106/120 decreasing by the threshold amount or being at or below a second temperature threshold value that is lower than the first temperature threshold value.

In some implementations, the inverter units 106/120 may have peak efficiencies at different power levels. E.g., some may have peak efficiency at relatively low power while others may have peak efficiency at relatively high power. Values of DC voltage setpoints of the inverter units 106/120 that have peak efficiency at relatively lower power may be set lower than values of DC voltage setpoints of the inverter units 106/120 that have peak efficiency at relatively higher power. For example, a first set of one or more of the inverter units 106/120 may have peak efficiency in a first power range and a second set of one or more of the inverter units 106/120 may have peak efficiency in a second power range, where a minimum value of the second power range is greater than a maximum value of the first power range. A DC voltage setpoint of each inverter unit 106/120 in the first set may have a lower value than a DC voltage setpoint of each inverter unit 106/120 in the second set. To ensure the inverter units 106/120 in the first set (e.g., that are more efficient at relatively low power) power on before inverter units 106/120 in the second set (e.g., that are more efficient at relatively high power).

Alternately or additionally, the inverter units 106/120 may distribute thermal energy as a group more readily than as individual inverter units 106/120, by trading off inverting power across inverter units operating near peak rooftop temperatures (each inverter unit 106/120 may curtail at or near the peak rooftop temperature to allow other lower temperature inverter units 106/120 to pick up the inversion (and thereby increase in temperature) while the curtailing inverter unit 106/120 drops in temperature). Stated another way, each of the inverter units 106/120 may be configured to curtail its AC power output responsive to a temperature of the corresponding inverter unit 106/120 reaching a first temperature threshold value. The curtailing inverter unit 106/120 may continue curtailing its AC power output until its temperature drops to a second temperature threshold value that is lower than the first temperature threshold value. Alternately or additionally, the non-curtailing inverter units 106/120 with temperatures below the first temperature threshold value may pick up the inversion.

The inverter units 106/120 in some implementations may be configured for binary operation including on at a single power level (e.g., no AC curtailment) or off and may be configured to operate in a relatively narrow voltage range that is less than or equal to the operating voltage range of the PV system 100. Such inverter units 106/120 may be simplified compared to other inverter units that are configured to operate at multiple power levels and/or wider voltage ranges and may be relatively less costly and more efficient.

Alternately or additionally, each inverter unit 106/120 may be configured to limit its AC output power (e.g., AC curtailment) while operating and in response to a power limiting command that indicates a target AC output power level for the corresponding inverter unit 106/120. The power limiting command may be received from the central control device 126.

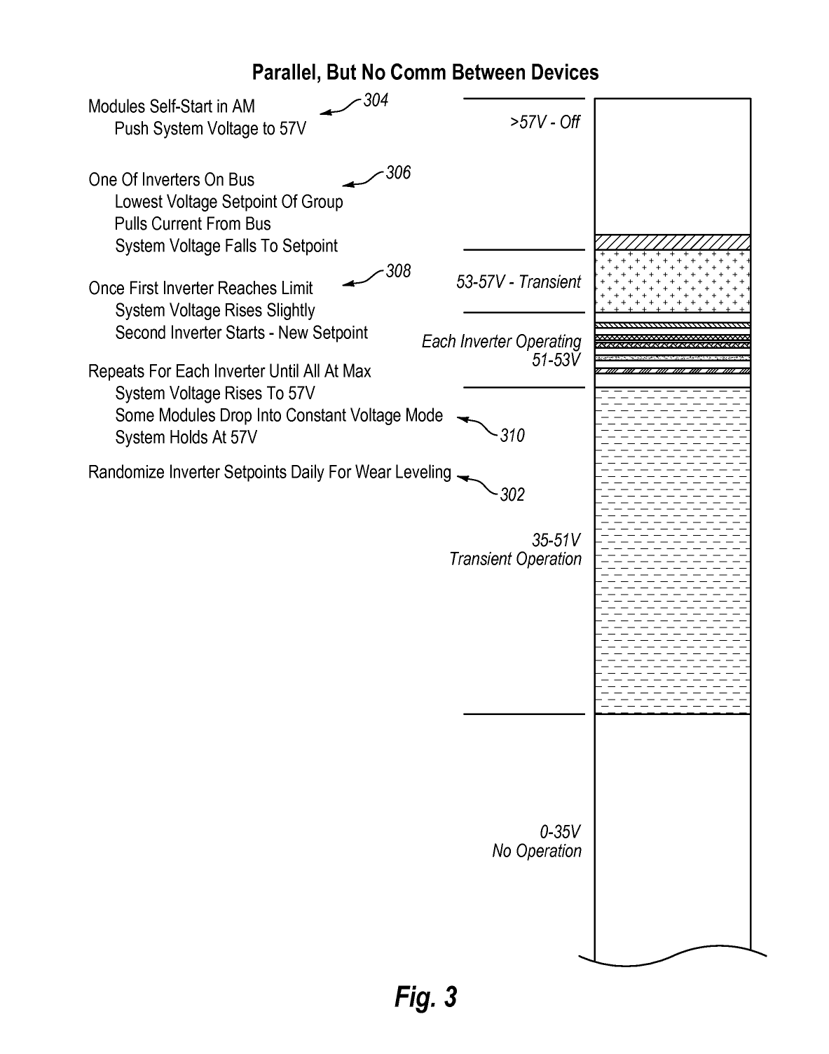

FIG. 3 conceptually illustrates DC bus voltage levels on the DC bus 102 of the PV system 100 and the resulting PV system 100 response, arranged in accordance with at least some embodiments described herein. The DC bus voltage levels are in the graph on the right and the PV system 100 response is described on the left of FIG. 3. In the example of FIG. 3, there is no communication internally between the inverter units 106, internally between the PV modules 104, and/or between the inverter units 106 and the PV modules 104. The DC voltage setpoints may be adjusted daily or at other times or according to other schedules for wear-leveling, as denoted at 302 in FIG. 3.

Under sufficient illumination, the PV modules 104 self-start and operate at maximum peak power to raise the DC bus voltage with increasing illumination, as denoted at 304 in FIG. 3.

As the DC bus voltage rises, it eventually reaches a value equal to the lowest DC voltage setpoint of at least one of the inverter units 106, which is about 51.0 volts in some implementations. The inverter unit 106 with the lowest DC voltage setpoint then powers on, pulling current from the DC bus 102 and causing the DC bus voltage to fall or remain at the lowest DC voltage setpoint, as denoted at 306 in FIG. 3.

After the first inverter unit 106 reaches its AC power output capacity, the DC bus voltage continues to rise until it reaches a value equal to a next DC voltage setpoint (e.g., the second-to-lowest) of a next inverter unit(s) 106 such that the next inverter unit(s) 106 power(s) on and causes the DC bus voltage to remain at the next DC voltage setpoint. Under sufficient illumination, the next inverter unit(s) 106 will eventually reach its (their) AC power output capacity, and other inverter units 106 will successively power on in order of lowest to highest DC voltage setpoint (e.g., 51 volts to 53 volts in the example of FIG. 3) as the DC bus voltage rises to each DC voltage setpoint. All of the foregoing is denoted at 308 in FIG. 3.

Under sufficient illumination, all of the inverter units 106 will reach their AC power output capacity and the DC bus voltage will be pushed to the upper threshold value of the operating voltage range, which is 57 volts in some implementations. At least some of the PV modules transition from maximum peak power to constant voltage mode responsive to detecting that the DC bus voltage is at the upper threshold value of the operating voltage range and the DC bus voltage may hold at the upper threshold value. All of the foregoing is denoted at 310 in FIG. 3.

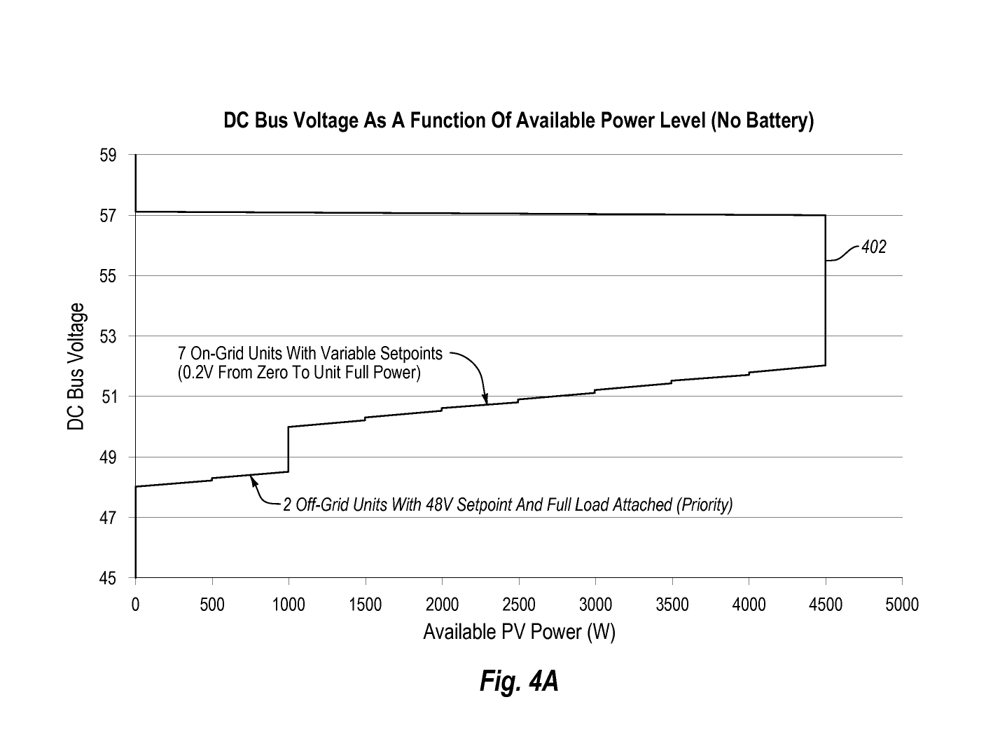

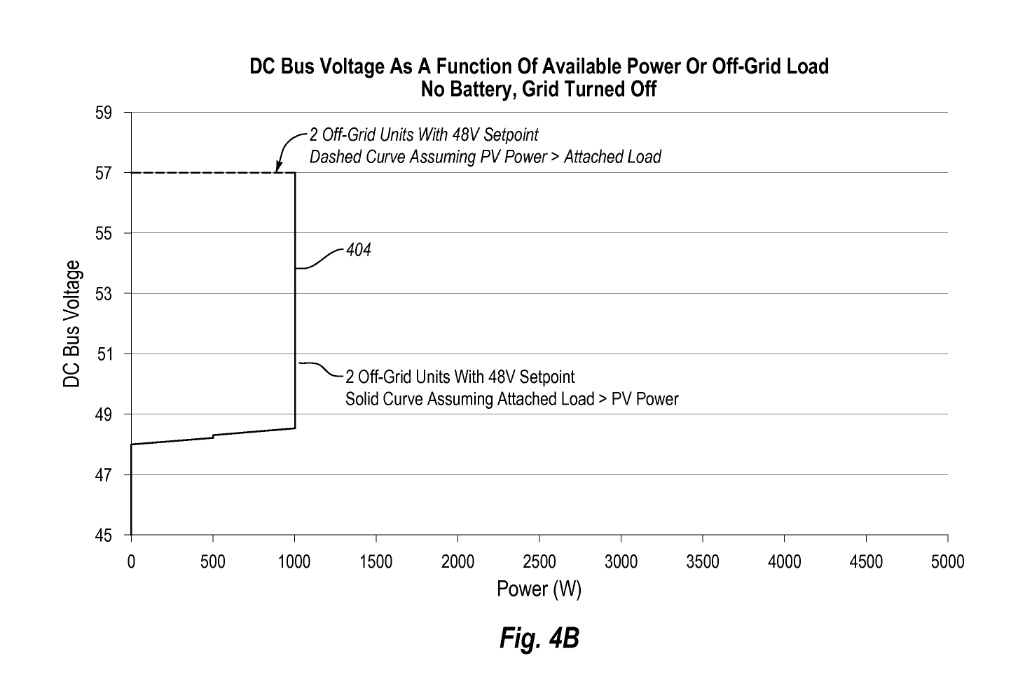

FIG. 4A illustrates a curve 402 that represents DC bus voltage (e.g., on the DC bus 102) as a function of available power level for the PV system 100B or 100C of FIG. 1B or 1C, arranged in accordance with at least some embodiments described herein. With combined reference to FIGS. 1B, 1C, and 4A, in the example of FIG. 4A, there are no energy storage devices coupled to the DC bus 102, the PV system 100B or 100C includes a total of nine inverter units 106/120, including seven inverter units 106 that are coupled to the AC grid 118 and two auxiliary inverter units 120 that are coupled to the auxiliary AC circuit 122, and it is assumed that there is a full electrical load on the auxiliary AC circuit 122 for the auxiliary inverter units 120. The seven inverter units 106 and the two auxiliary inverter units 120 are each 500 watt inverter units. The two auxiliary inverter units 120 respectively have DC voltage setpoints of 48.0 and 48.3 volts and the seven inverter units 106 respectively have DC voltage setpoints of 50.0, 50.3, 50.6, 50.9, 51.2, 51.5, and 51.8 volts. As illustrated in FIG. 4A, the DC voltage setpoint of each of the inverter units 106/120 has a finite slope of DC voltage setpoint versus power of about 0.2 volts per 500 watts.

As illustrated in FIG. 4A, the first auxiliary inverter unit 120 powers on when the DC bus voltage is at 48.0 volts and its DC voltage setpoint increases by about 0.2 volts until reaching the AC power output capacity (e.g., 500 watts) of the first auxiliary inverter unit 120. The DC bus voltage then rises to 48.3 volts where the second auxiliary inverter unit 120 powers on and its DC voltage setpoint increases by about 0.2 volts until reaching the AC power output capacity of the second auxiliary inverter unit 120. At this point, the total available power is the sum of the AC power output capacities of the two auxiliary inverter units 120, or 1000 watts.

The DC bus voltage then rises to the next voltage setpoint, or 50.0 volts, where the first inverter unit 106 powers on and its DC voltage setpoint increases by about 0.2 volts until reaching the AC power output capacity of the first inverter unit 106. The DC bus voltage then rises to 50.3 volts where the second inverter unit 106 powers on and its DC voltage setpoint increases by about 0.2 volts until reaching the AC power output capacity of the second inverter unit 106. The other remaining inverter units 106 continue powering on as the DC bus voltage reaches their respective voltage setpoints, adding their AC power output capacities to the total available power.

The climb in total available power continues until the total available power reaches the maximum aggregate capacity (e.g., 4500 watts) of the inverter units 106/120. At this point, the DC bus voltage rises to 57 volts and at least some of the PV modules 102 drop to constant voltage mode as described elsewhere.

FIG. 4B illustrates another curve 404 that represents DC bus voltage (e.g., on the DC bus 102) as a function of available power level for the PV system 100B or 100C of FIG. 1B or 1C, arranged in accordance with at least some embodiments described herein. With combined reference to FIGS. 1B, 1C, and 4B, in the example of FIG. 4B, there are no energy storage devices coupled to the DC bus 102, The AC grid 118 is down (e.g., turned off), the PV system 100B or 100C includes two auxiliary inverter units 120 that are coupled to the auxiliary AC circuit 122, and it is assumed that there is a full electrical load on the auxiliary AC circuit 122 for the auxiliary inverter units 120. The two auxiliary inverter units 120 are each 500 watt inverter units. The two auxiliary inverter units 120 respectively have DC voltage setpoints of 48.0 and 48.3 volts. As illustrated in FIG. 4B, the DC voltage setpoint of each of the inverter units 120 has a finite slope of DC voltage setpoint versus power of about 0.2 volts per 500 watts. The operation of the auxiliary inverter units 120 in FIG. 4B is similar to FIG. 4A and will not be described again.

Provided the electrical load coupled to the auxiliary AC circuit 122 is a full load and the PV power is greater than the electrical load, each of the two auxiliary inverter units 120 will power on, the DC bus voltage will eventually rise to 57 volts, and some of the PV modules 102 will operate in constant voltage mode to maintain the DC bus voltage 57 volts.

B. Example Inverter Unit

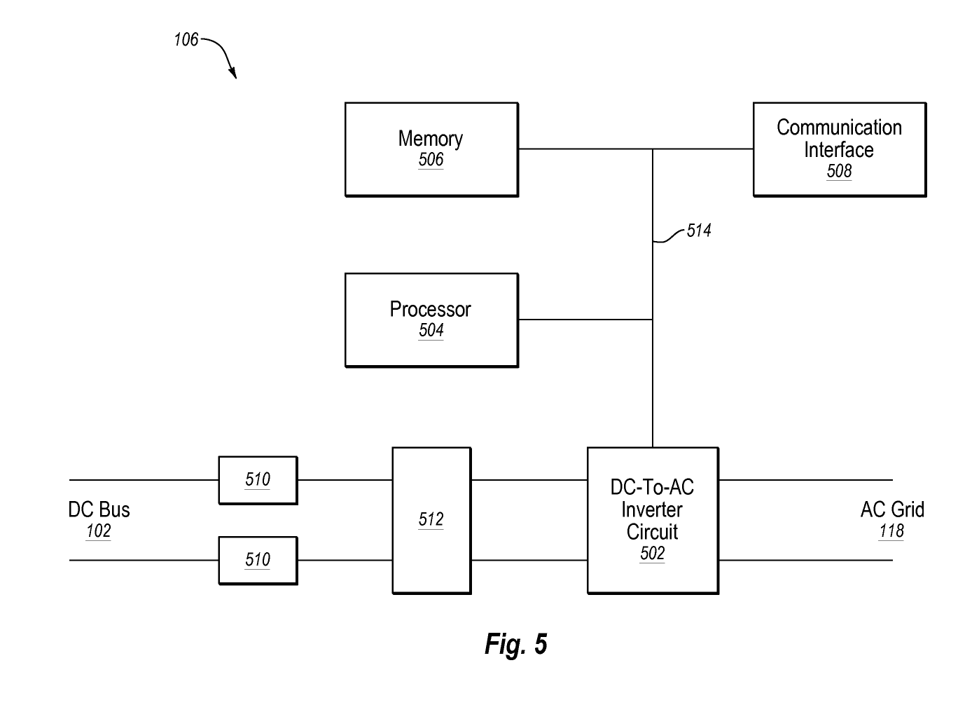

FIG. 5 is a block diagram of an embodiment of one of the inverter units 106 of FIGS. 1A-2, arranged in accordance with at least some embodiments described herein. Each of the inverter units 106, the auxiliary inverter units 120, and/or the failover inverter units described herein may be similarly configured. The inverter unit 106 illustrated in FIG. 5 is merely one example of an inverter unit that can be employed according to some embodiments.

The inverter unit 106 may include at least a DC-to-AC inverter circuit 502 electrically coupled to the DC bus 102 and the AC grid 118. The DC-to-AC inverter circuit 502 may be configured to convert DC power received on the DC bus 102 to AC power output to the AC grid 118. In some implementations, the DC-to-AC inverter circuit 502 has a fixed DC voltage setpoint, while in other implementations the DC-to-AC inverter circuit 502 has an adjustable DC voltage setpoint.

The DC-to-AC inverter circuit 502 and/or the inverter unit 106 of FIG. 5 may have any suitable topology. In an example implementation, the DC-to-AC inverter circuit 502, or more generally the inverter unit 106 of FIG. 5, includes one or more DC-to-DC converters (e.g., using a high frequency isolation transformer), some capacitance, and a DC-to-AC converter (e.g., an H-bridge and some filtering units).

In implementations in which there are at least two DC-to-DC converters, each of the DC-to-DC converters may have its own DC-to-DC voltage setpoint, which may be adjusted similar to the DC voltage setpoints as described herein. In these and other implementations, the multiple DC-to-DC voltage setpoints of each of the inverter units 106/120 may provide additional granularity to the voltage ladder implemented in the PV systems 100 described herein.

The inverter unit 106 may alternately or additionally include one or more of a processor 504, a memory 506, a communication interface 508, one or more overcurrent protection devices 510, and one or more measurement circuits 512. Two or more of the DC-to-AC inverter circuit 502, the processor 504, the memory 506, and the communication interface 508 may be communicatively coupled by a bus 514. The bus 514 may include, but is not limited to, a memory bus, a storage interface bus, a bus/interface controller, an interface bus, or the like or any combination thereof.

The processor 504 includes an arithmetic logic unit, a microprocessor, a general-purpose controller, or some other processor array to perform or control performance of operations as described herein. The processor 504 generally processes data signals and may include various computing architectures including a complex instruction set computer (CISC) architecture, a reduced instruction set computer (RISC) architecture, or an architecture implementing a combination of instruction sets.

The processor 504 may be configured to control operation of the DC-to-AC inverter circuit 502 and more generally of the inverter unit 106. For example, the processor 504 may set or adjust the DC voltage setpoint and/or an AC curtailment of the inverter unit 106. The processor 504 may receive signals or commands from a central control device, e.g., the central control device 126 (FIG. 1C), and may receive and execute the signals or commands to make the adjustments to the DC voltage setpoint and/or the AC curtailment. Alternately or additionally, the processor 504 may retrieve one or more discrete values from the memory 506 to set as the DC voltage setpoint or AC curtailment according to a pre-programmed rotation. Alternately or additionally, the processor 504 may execute a random or pseudo-random DC setpoint adjustment algorithm stored in the memory as computer-readable instructions executable by the processor 504 to adjust the DC voltage setpoint.

The memory 506 stores instructions or data that may be executed or operated on by the processor 504. The instructions or data may include computer-readable instructions including programming code that may be executed by the processor 504 to perform or control performance of the operations described herein. The memory 506 may include a dynamic random access memory (DRAM) device, a static random access memory (SRAM) device, flash memory, or some other memory device. In some implementations, the memory 506 also includes a non-volatile memory or similar permanent storage and media including a hard disk drive, a floppy disk drive, a CD-ROM device, a DVD-ROM device, a DVD-RAM device, a DVD-RW device, a flash memory device, or some other mass storage for storing information on a more permanent basis.

For example, the memory 506 may store the discrete values to set as the DC voltage setpoint or AC curtailment according to the pre-programmed rotation. Alternately or additionally, the memory 506 may store the random or pseudo-random DC setpoint adjustment algorithm. In some implementations, the memory 506, and more generally, the inverter unit 106, does not include or implement an MPPT algorithm. Instead, and as already described above, MPPT (e.g., operating at maximum peak power) may be implemented independently by each of the PV modules 104.

The communication interface 508 transmits and receives data, signals, and/or commands to and from at least one of a central control device, e.g., the central control device 126 (FIG. 1C), other inverter units 106, and any other communication-enabled components of the PV systems 100 described herein FIG. 1. In some implementations, the communication interface 508 includes a port for direct physical connection to a communication channel, such as a modbus, a CAN bus, a PLC communication channel, an RF communication channel, or other communication channel to communicate with other communication-enabled components. For example, the communication interface 508 may include a universal serial bus (USB) port, a secure digital (SD) port, a category 5 cable (CAT-5) port, or similar port for wired communication with other communication-enabled components of the PV systems 100 described herein. In some implementations, the communication interface 508 includes an RF transceiver.

Each of the overcurrent protection devices 510 is coupled between the inverter unit 106 and the DC bus 102. One or more of the overcurrent protection devices 510 may be included internally to and as part of the inverter unit 106. Alternately or additionally, one or more of the overcurrent protection devices 510 may be external to the inverter unit 106. Each of the overcurrent protection devices 510 is configured to protect the inverter unit 106 by electrically isolating the inverter unit 106 from the DC bus 102 in response to current on the DC bus 102 reaching a value that may cause an excessive or dangerous temperature rise in the inverter unit 106 and/or in response to detecting a short circuit or ground fault.

The measurement circuit 512 includes one or more resistors and is configured to measure certain operating parameters of the inverter unit 106. For instance, the measurement circuit 512 can measure the voltage on the DC bus 102, e.g., the DC bus voltage. Although illustrated as separate from the DC-to-AC inverter circuit 502, the measurement circuit 512 may be included within the DC-to-AC inverter circuit 502. In these and other implementations, the measured DC bus voltage may be compared to the DC voltage setpoint to determine whether to power on the inverter unit 106.

C. Common Housing Unit

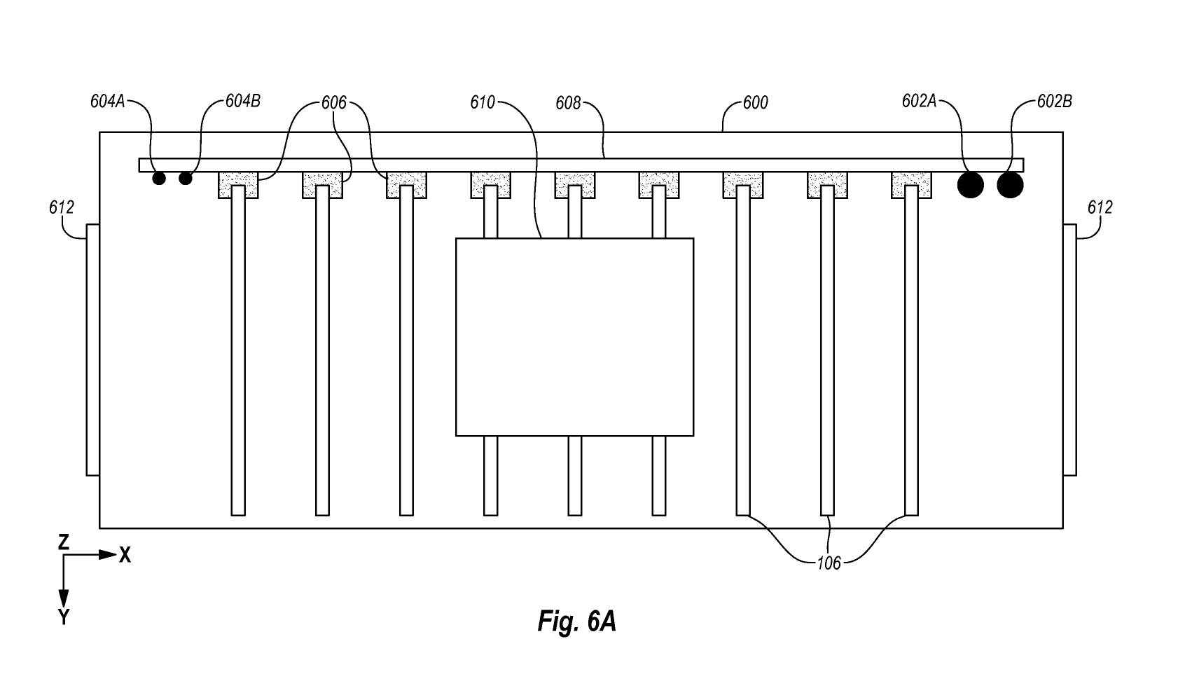

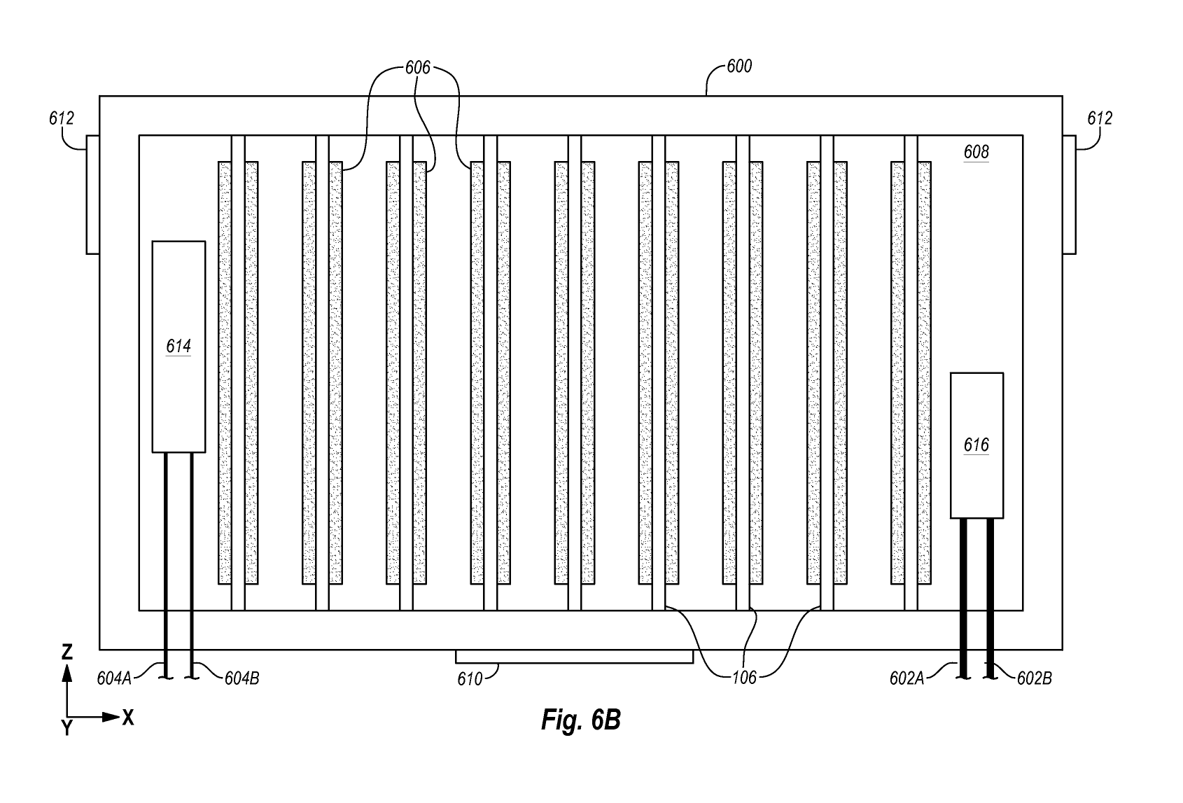

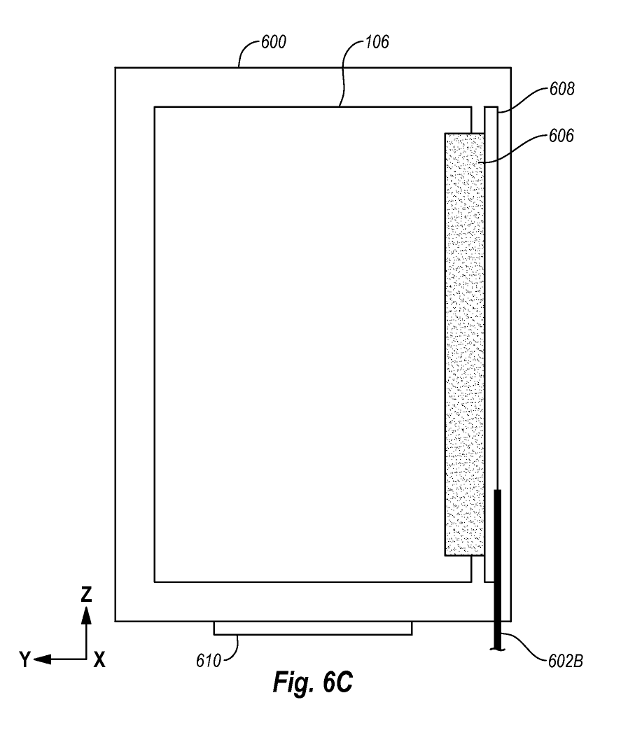

In some embodiments, each of the inverter units 106/120 are packaged as discrete components. In other embodiments, the inverter units 106/120 may be packaged together in a common housing unit, as will now be described. FIGS. 6A-6C illustrate, respectively, a top view, a front view, and a side view of an example common housing unit 600, arranged in accordance with at least some embodiments described herein. FIGS. 6A-6C additionally include an arbitrarily defined x-y-z coordinate axis to provide a reference frame between the Figures.

The common housing unit 600 may include an enclosure within which the inverter units 106/120 are positioned. For simplicity, the embodiment of FIGS. 6A-6C only includes inverter units 106, only some of which are labeled. The inverter units 106 are implemented in FIGS. 6A-6C as printed circuit board (PCB) cards each having thereon a DC-to-AC inverter circuit, such as the DC-to-AC inverter circuit 502 of FIG. 5.

FIGS. 6A-6C further illustrate input leads 602A and 602B (collectively “input leads 602”), output leads 604A and 604B (collectively output leads 604″), card slots 606 (only some of which are labeled for simplicity), a PCB backplane 608, a cooling fan 610, one or more louvers 612, a communication interface 614, and a protection device 616.

The input leads 602 may be coupled to the DC bus 102 described above and may receive DC power from the DC bus 102. The output leads 604 may be coupled to the AC grid 118 described above and may output AC power to the AC grid 118.

Each of the card slots 606 may be configured to receive a different inverter unit 106 implemented as a PCB card. The card slots 606 mechanically retain the inverter units 106 and provide an electrical interface between the inverter units 106 and the PCB backplane 608.

The PCB backplane 608 provides electrical connections from the DC bus 102 to the inverter units 106 via the input leads 602 and from the inverter units 106 to the AC grid 118 via the output leads 604. The electrical connections of the PCB backplane 608 and the input leads 602 may electrically couple DC inputs of the inverter units 106 in parallel to the DC bus 102. The electrical connections of the PCB backplane 608 and the output leads 604 may electrically coupled AC outputs of the inverter units 106 to the AC grid 118. The output leads 604 may be referred to as a common AC output bus that is electrically coupled to the AC grid 118 and that electrically couples the inverter units 106 to the AC grid 118.

Alternately or additionally, the PCB backplane 608 may include at least one common component that is shared between two or more of the inverter units 106. The common component(s) shared between two or more of the inverter units 106 may include capacitors, filtering inductors, or other components.

The cooling fan 610 may be configured to circulate air to cool the inverter units 106.

The louvers 612 may include fins or other large surface area structures to dissipate heat generated by the inverter units 106 to the surrounding environment.

The communication interface 614 may correspond to the communication interface 508 of FIG. 5. The communication interface 614 may include an RF transceiver, a PLC transceiver or controller, or other suitable communication interface.

The protection device 616 may include an overcurrent protection device such as the overcurrent protection devices 510 of FIG. 5, a circuit breaker, a ground fault detect/interrupt device, or other suitable protection device. The protection device 616 may be electrically coupled between the PCB backplane 608 and the input leads 602 (and therefore the DC bus 102).

### III. PV Module

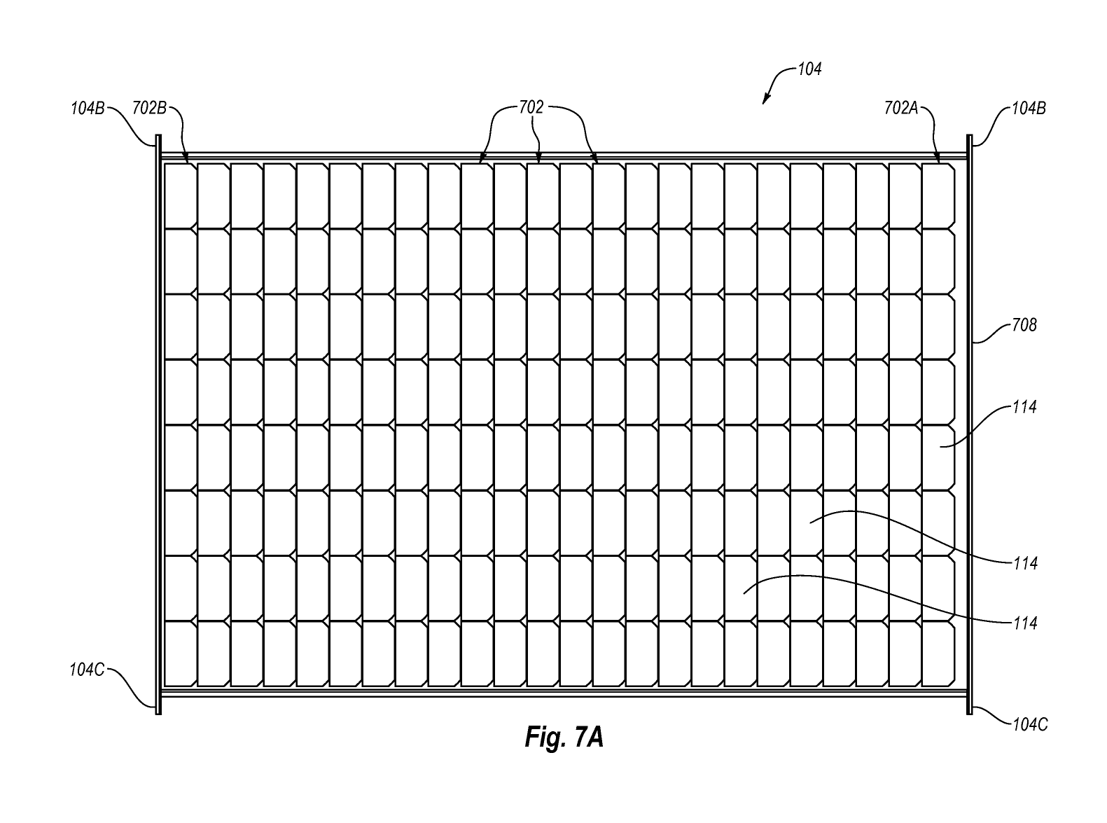

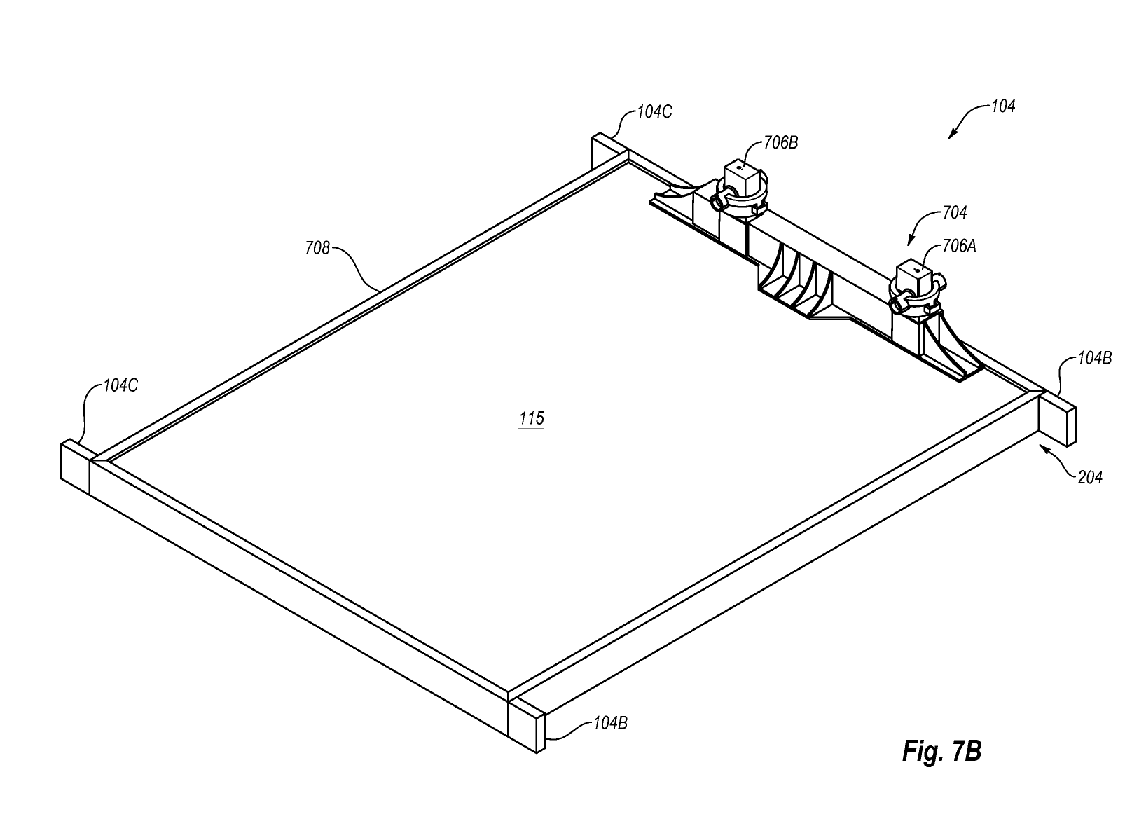

FIGS. 7A and 7B include a front view and a back view of an example of one of the PV modules 104 of FIGS. 1A-2, arranged in accordance with at least some embodiments described herein. As best seen in FIG. 7A, the PV module 104 includes the PV cells 114 (only some of which are labeled for simplicity) arranged in cell rows 702 (only some of which are labeled for simplicity). The cell rows 702 include a first row 702A and a last row 702B. Further, the cell rows 702 are electrically connected in a mesh topology as described above such that, in operation, current generally flows uni-directionally through the PV cells 114. In the example of FIG. 7A, for instance, current generally flows through all of the PV cells 114 from left to right. Additional details regarding some example PV modules that may be implemented in the PV systems 100 described herein are disclosed in U.S. patent application Ser. No. 13/664,885.

As best seen in FIG. 7B, the PV module 104 includes the backsheet 115 and an undermount assembly 704 with output terminals 706A, 706B (generically referred to in the singular or plural as “output terminal 706” or “output terminals 706”). Output terminal 706A includes a negative output terminal and output terminal 706B includes a positive terminal in the illustrated embodiment. Each of the output terminals 706 may include a self-tapping bus connector that electrically couples the PV module 104 to the DC bus 102 (FIGS. 1A-1C). In some implementations, each of the self-tapping bus connectors has a cross-sectional area of at least 33 mm². Additional details regarding example backsheets, undermount assemblies, output terminals, and self-tapping bus connectors (also referred to as risers) that may be implemented in the PV modules 104 described herein are disclosed in U.S. patent application Ser. No. 13/664,885.

With combined reference to FIGS. 7A and 7B, the PV module 104 further includes a frame 708 extending around all or a portion of the perimeter of the PV module 104, as previously mentioned with respect to FIG. 2. Although not required, the PV module 104 as illustrated in FIGS. 7A-7B includes the upper frame extensions 104B and lower frame extensions 104C disposed at the four corners of the frame 708 for use in interconnecting the PV module 104 to one or more other PV modules 104, to one or more reflectors 202, and/or to the racking assembly 204 in the PV systems 100 of FIGS. 1A-2. Additional details regarding example frame extensions and PV module arrays that may be implemented herein are disclosed in U.S. patent application Ser. No. 13/957,227.

### IV. Converter

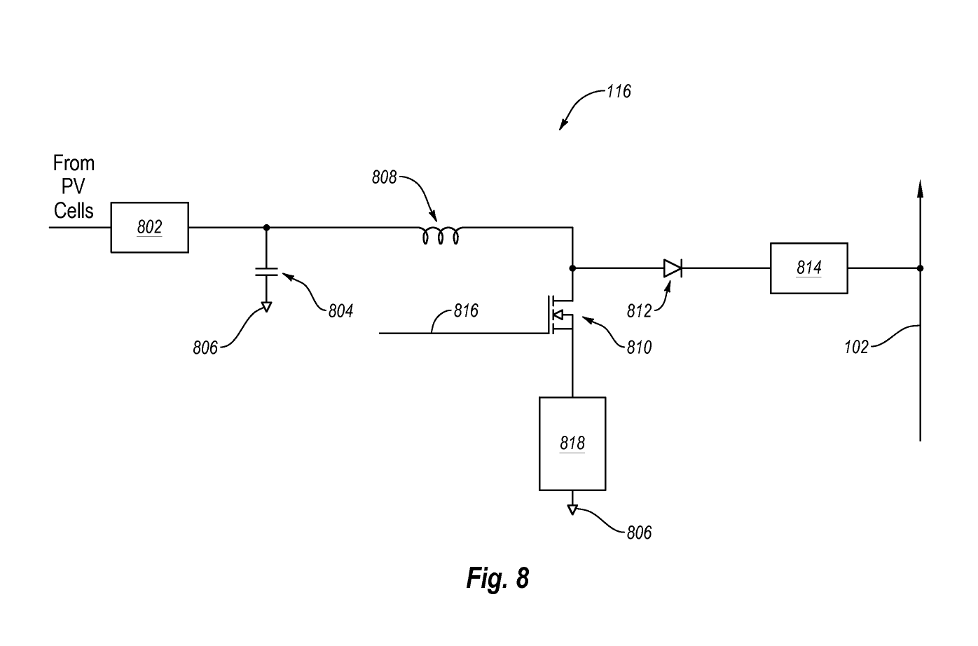

FIG. 8 is a schematic diagram of an embodiment of one of the converters 116 of FIGS. 1A-1C, arranged in accordance with at least some embodiments described herein. Each of the converters 116 may be similarly configured and the converters 116 may be housed within the undermount assembly 704 of FIG. 7B on a circuit card. The converter 116 illustrated in FIG. 8 is merely one example of a converter that can be employed according to some embodiments.

The converters 116 may generally be configured to provide power conditioning of the electrical power generated by the PV cells 114 of the corresponding PV module 104, thereby delivering conditioned power output to the DC bus 102. In some embodiments, “power conditioning” includes stepping up the voltage to a predetermined output voltage; maintaining maximum peak power within the PV cells 114 of the corresponding PV module 104; reducing current ripple at an input and output of the undermount assembly 704; detecting, monitoring, and maintaining a programmed charge profile for one or more batteries directly connected to the output of the undermount assembly 704; and/or maintaining a constant voltage source. Accordingly, conditioned power output may include power output to the DC bus 102 with a stepped up voltage, maximum peak power, reduced current ripple, or the like. By implementing an undermount assembly 704 with such converters 116 in each of the PV modules 104 in the PV systems 100 described herein, each of the PV modules 104 independently controls its own power conditioning to maximize efficiency of the PV systems 100 described herein.

As shown in FIG. 8, the converter 116 includes an input 802, a capacitor 804 coupled to the input 802 and to ground 806, an inductor 808 coupled to the input 802 and to the capacitor 804, a switch 810 coupled to the inductor 808, a diode 812 coupled to the inductor 808 and to the switch 810, an output 814 coupled to the diode 812, a control line 816 coupled to the switch 810, and one or more measurement circuits 818 coupled between the converter 116 and ground 806.

With combined reference to FIGS. 1A-2 and 7A-8, the input 802 is electrically coupled to receive power collectively generated by the PV cells 114. The ground 806 is electrically coupled to the backsheet 115. The output 814 is electrically coupled to the DC bus 102. The control line 816 is communicatively coupled to a digital controller that may be included in the undermount assembly 704.

The digital controller provides, via the control line 816, a PWM signal to the switch 810 that controls a switching frequency and/or a duty cycle of the converter 116. Alternately or additionally, the PWM signal controls the phasing of the converter 116 relative to the phasing of the other converters 116.

The switch 810 may include a field-effect transistor (“FET”), a metal-oxide-semiconductor FET (“MOSFET”), an insulated-gate bipolar transistor (“IGBT”), a bipolar junction transistor (“BJT”), or other suitable switch. The diode 812 may include a Schottky rectifier, or other suitable diode. Alternately, a FET or other suitable switch may be implemented in place of the diode 812 and may operate in a synchronous rectification mode.

The measurement circuit 818 includes one or more resistors and is employed to measure certain operating parameters of the converter 116. For instance, the measurement circuit 818 can measure the maximum current buildup per switching cycle in the inductor 808 in order to maintain maximum peak power. Alternately or additionally, the measurement circuit 818 can measure the charging rate of the inductor 808, the input voltage of the converter 116, the output voltage of the converter 116, or the like or any combination thereof.

In operation, the converter 116 receives energy generated by any of the PV cells 114 at the input 802 and converts it to have a relatively higher voltage (referred to as the “step-up voltage”) and a lower current by switching itself on and off via the switch 810. In the “on” state, the switch 810 is closed such that the current flowing through the inductor 808 increases and returns to ground 806 through the switch 810 and the measurement circuit 818. In the “off” state, the switch 810 is open such that the current flowing through the inductor 808 decreases, flowing through the diode 812 and the output 814 to the output bus 102.

In the “on” state of the converter 116, the voltage at the output 814 is about 0 volts. In the “off” state, the voltage at the output 814 depends on the rate of change of current through the inductor 808, rather than on the input voltage at the input 802. In turn, the rate of change of current through the inductor 808 depends on the inductance of the inductor 808. Accordingly, the step-up voltage at the output 814 depends on the inductance of the inductor 808. Alternately or additionally, the step-up voltage at the output 814 depends on the switching frequency of the switch 810 and/or the duty cycle of the switch 810.

In a continuous conduction mode, the current through the inductor 808 never reaches 0 amps. By cycling the converter 116 on and off in or near continuous conduction mode, the converter 116 produces conditioned power (e.g., power having the step-up voltage) at the output 814 while maximizing efficiency and minimizing peak current in the converter 116. Alternately or additionally, the converter 116 may be operated near continuous conduction mode by limiting the duty cycle D of the converter 116 to [(V_out−V_in)/V_out−0.05]<D<0.75, where V_out and V_in are the output voltage and the input voltage of the converter 116 and may be measured by the measurement circuit 818.

In this and other embodiments, the switch 810 is operated via the control line 816. In particular, the digital controller sends signals over the control line 816 to open and close the switch 810 at a desired frequency and duty cycle. Because each of the step-up voltage and the impedance of the converter 116 depend on the frequency and the duty cycle of the switching process, the digital controller can set the frequency and/or duty cycle at a predetermined frequency and/or duty cycle to optimize the step-up voltage and the impedance of the converter 116. Thus, any individual converter 116 may only be partially used in both duty cycle and frequency and may be part of a dynamic load-leveling cycle.

In some embodiments, the increasing and decreasing current through the inductor 808 can cause periodic variations in the amplitude of the input current and/or the output current of the converter 116. These periodic variations in the current amplitude are also known as current ripple. Current ripple at the input 802 of the converter 116 can cause the impedance of the converter 116 to vary as a function of the current ripple, making it difficult for the converter 116 to maintain maximum peak power. Current ripple at the output of the converter 116 can result in noise on the output bus 102 that may negatively affect a load coupled to the output bus 102.

However, current ripple can be substantially reduced at the input and output of the circuit card (e.g., the input and output of the converters 116) as a whole by operating the converters 116 out of phase with each other. When the converters 116 are operating out of phase with each other, the amplitude of current ripple in one of the converters 116 may be increasing while the amplitude of current ripple in another of the converters 116 may be decreasing. The cumulative effect of the out-of-phase operation of the converters 116 may average out the current ripple at the input and output of the circuit card as a whole.

As mentioned above, the maximum value of the current buildup and/or the charging rate of the inductor 808 may be used by the converters 116 in maintaining peak power of the corresponding PV modules 104. Maintaining peak power can maximize the unconditioned power output of the array of PV cells 114, and consequently of the conditioned power output to the DC bus 102. In general, maintaining peak power includes (1) identifying a peak power point at which power output of the array of PV cells 114 is maximized and (2) dynamically varying the impedance of the converters 116 to effectively match the impedance of a load such that the voltage across the array of PV cells 114 is substantially equal to the identified peak power point. Details of an example peak power algorithm are disclosed in more detail in U.S. patent application Ser. No. 12/357,260, filed Jan. 21, 2009, which application is herein incorporated by reference in its entirety.

Each of the PV modules 104 of the PV systems 100 described herein may include converters 116 such as described with respect to FIG. 8. Accordingly, each of the PV modules 104 may be configured to independently control a composite electrical impedance of one or more of its converters 116 to operate at maximum peak power as described above in response to the corresponding PV module 104 detecting that a value of the DC bus voltage is between a first threshold value and a second threshold value greater than the first threshold value. In some implementations, the first and second threshold values may be 35 volts and 57 volts, respectively. A startup sequence that includes raising the DC bus voltage to the first threshold value prior to operating at maximum peak power and that may be implemented in the embodiments disclosed herein is described in U.S. patent application Ser. No. 12/815,913

In these and other implementations, the PV modules 104 may be configured to determine capacitance available to the PV system 100 at startup and impedance across a power range. The impedance may include the collective impedance of the inverter units 106/120 coupled to the DC bus 102. The power range may include the range over which the PV modules 104 can collectively operate, which may include a range from 0 watts to the aggregate power output capacity of the PV modules 104 at standard test conditions (e.g., 25° C., 1000 Watts per meter squared (W/m²) illumination power).

Alternately or additionally, each of the PV modules 104 may be configured to independently transition from operation at maximum peak power to a constant voltage mode in response to the corresponding PV module 104 detecting that the value of the DC bus voltage is greater than the second threshold value. Due to, e.g., calibration differences, the PV modules 104 may not detect the same DC bus voltage at any given time. As such, those PV modules 104 that detect the DC bus voltage as greater than the second threshold value first may transition to the constant voltage mode first. In some circumstances, some PV modules 104 may not detect the DC bus voltage as greater than the second threshold value if sufficient other PV modules 104 transition to the constant voltage mode and thereby keep the DC bus voltage at a level beneath where the non-detecting PV modules 104 would detect the DC bus voltage as greater than the second threshold value.

In some implementations, a DC capacity of the PV modules 104 is significantly larger than an AC capacity of the inverter units 106/120 without requiring the DC wiring (e.g., the DC bus 102) to be sized to the DC capacity. The DC capacity of the PV modules 104 refers to the aggregate power output capacity of the PV modules 104 at the standard test conditions. The AC capacity of the inverter units 106/120 refers to the aggregate maximum AC power output capacity of the inverter units 106/120, typically defined as nominal AC voltage and maximum AC current output. The DC capacity may be about two (or more) times greater than the AC capacity and a size of the DC bus may be smaller than and not matched to the DC capacity. Instead, the size of the DC bus may be matched to the relatively lower AC capacity since the PV modules 104 individually implement power curtailment (e.g., transitioning to constant voltage mode) as needed. The difference between the DC capacity and the AC capacity may provide a more desirable AC power output from the PV systems described herein in which the AC power output has relatively less dependence on variations in illumination, reaches a maximum earlier in the day and maintains the maximum later in the day as compared to PV systems in which the DC capacity matches or more closely matches the AC capacity.

### V. Mechanical Attachment of Inverter Units

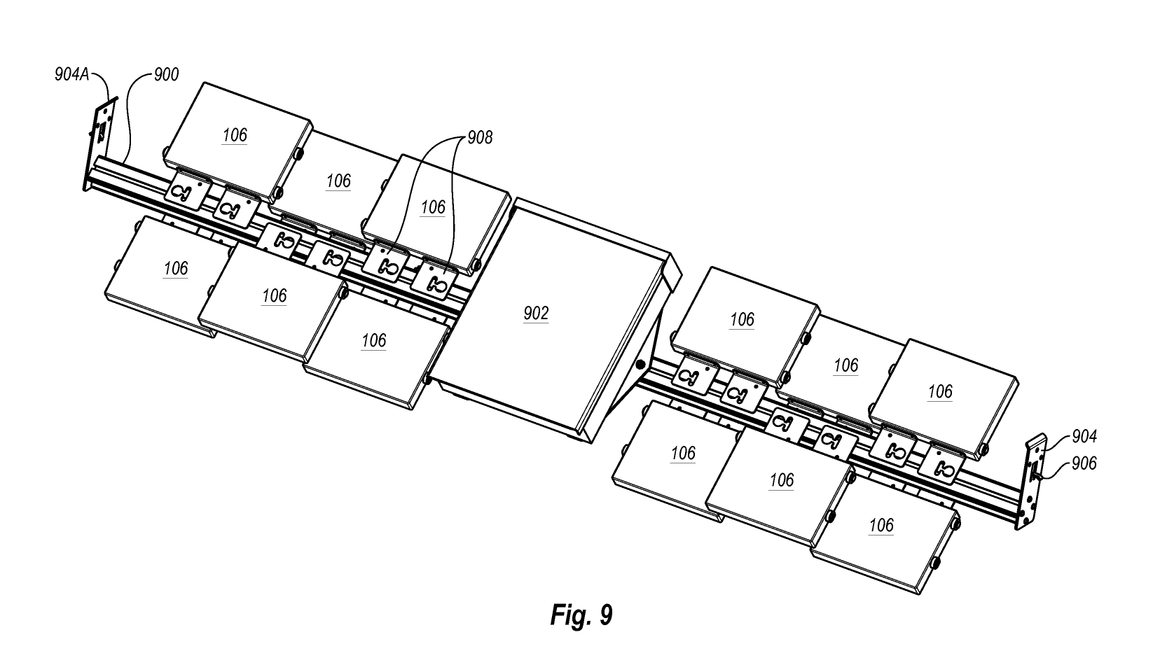

FIG. 9 is a perspective view of an example of an elongate support 900 and the inverter units 106 of FIGS. 1A-1C, arranged in accordance with at least some embodiments described herein. FIG. 9 further illustrates an optional fused combiner 902 and end plates 904A and 904B (collectively “end plates 904”).

Electrical connections from the DC inputs of the inverters 106 to the DC bus 102 may be routed through the fused combiner 902. Alternately or additionally, the AC outputs of the inverter units 106 may be daisychained in parallel (e.g., electrically connected in parallel) to the AC grid 118.

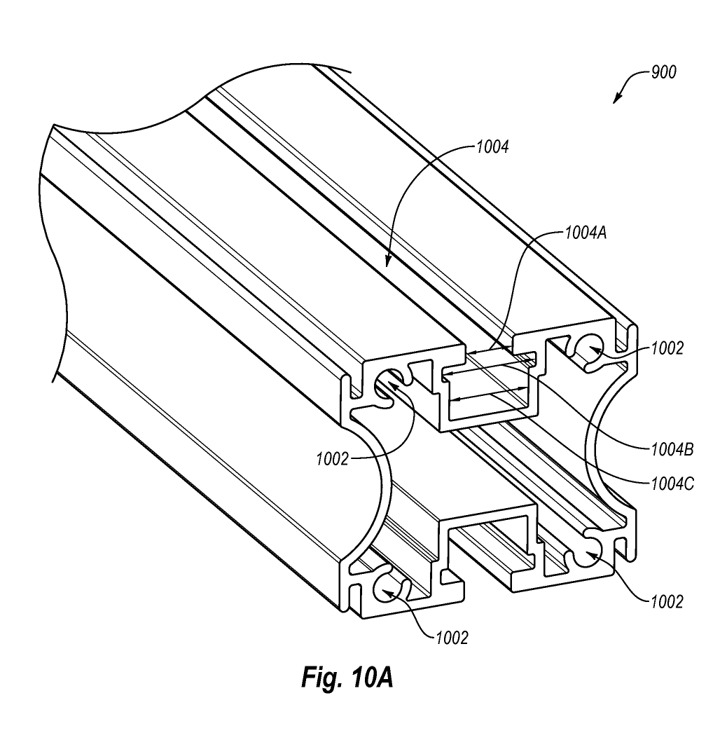

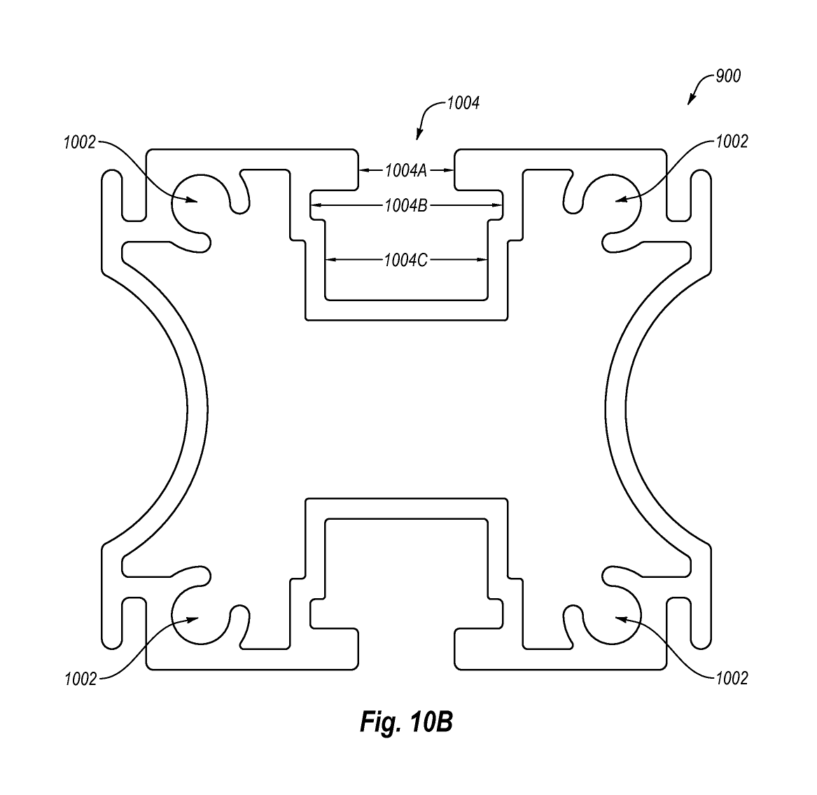

FIGS. 10A and 10B include a perspective end view and an end view of the elongate support 900 of FIG. 9, arranged in accordance with at least some embodiments described herein.

With combined reference to FIGS. 9-10B, the elongate support 900 may include an extruded rod formed from any suitable material, such as aluminum. The elongate support 900 may alternately or additionally include one or more extruded semi-cylindrical slots 1002 that extend in a direct parallel to the length of the elongate support 900. In some implementations, the extruded semi-cylindrical slots 1002 may extend an entire length of the elongate support 900. The end plates 904 may be mechanically coupled to opposite ends of the elongate support 900 by at least one screw at each of the opposite ends. The screw may be threadably received in a corresponding one of the extruded semi-cylindrical slots 1002.

For example, the end plate 904A may be mechanically coupled to a first end of the elongate support 900 by one, two, three, or four screws threadably received in the corresponding extruded semi-cylindrical slots 1002 at the first end of the elongate support 900. Analogously, the end plate 904B may be mechanically coupled to the opposite end of the elongate support 900 by one, two, three, or four screws threadably received in the corresponding extruded semi-cylindrical slots 1002 at the opposite end of the elongate support 900.

The end plates 904 may be configured to mechanically couple the elongate support 900 with the attached inverter units 106 and fused combiner 902 to the PV system 100. For example, the end plates may be configured to mechanically couple the elongate support 900 with the attached inverter units 106 and fused combiner 902 to a frame of a reflector within the PV system 100, such as the frame 202 of the reflector 202 of the PV system 100 of FIG. 2. Alternately or additionally, the end plates 904 may electrically ground the elongate support 900 with the attached inverter units 106 to a ground of the PV system.

In some implementations, each of the end plates 904 includes at least one tongue 906 (only one of which is labeled for simplicity) described in more detail below. The tongue 906 may be stamped from each of the end plates 904.

As illustrated in FIGS. 10A-10B, the elongate support 900 may further include one or more channels 1004 (only one of which is labeled for simplicity) that run a length of the elongate support 900. Each of the channels 1004 may include a neck portion, a washer portion, and a head portion, respectively denoted generally at 1004A, 1004B, and 1004C.

A width of the neck portion 1004A may be sized to accommodate therebetween a shaft portion of each of multiple threaded fasteners that are used to mechanically couple the inverter units 106 to the elongate support 900. E.g., the width of the neck portion 1004A may be slightly larger than a diameter of the shaft portion of the threaded fasteners.

A width of the washer portion 1004B may be sized to accommodate therebetween a washer that is in the shaft portion of the threaded fastener. E.g., the width of the washer portion 1004B may be slightly larger than a diameter of the washer.

A width of the head portion 1004C may be sized to accommodate therebetween a head portion of each of the threaded fasteners that are used to mechanically couple the inverter units 106 to the elongate support 900. E.g., the width of the head portion 1004A may be slightly larger than a diameter of the head portion of the threaded fasteners.

With combined reference to FIGS. 9-10B, one or more inverter brackets 908 (only some of which are labeled for simplicity) coupled to or extending from each of the inverter units 106 may be mechanically coupled to and electrically grounded to the elongate support 900 using the aforementioned threaded fasteners.

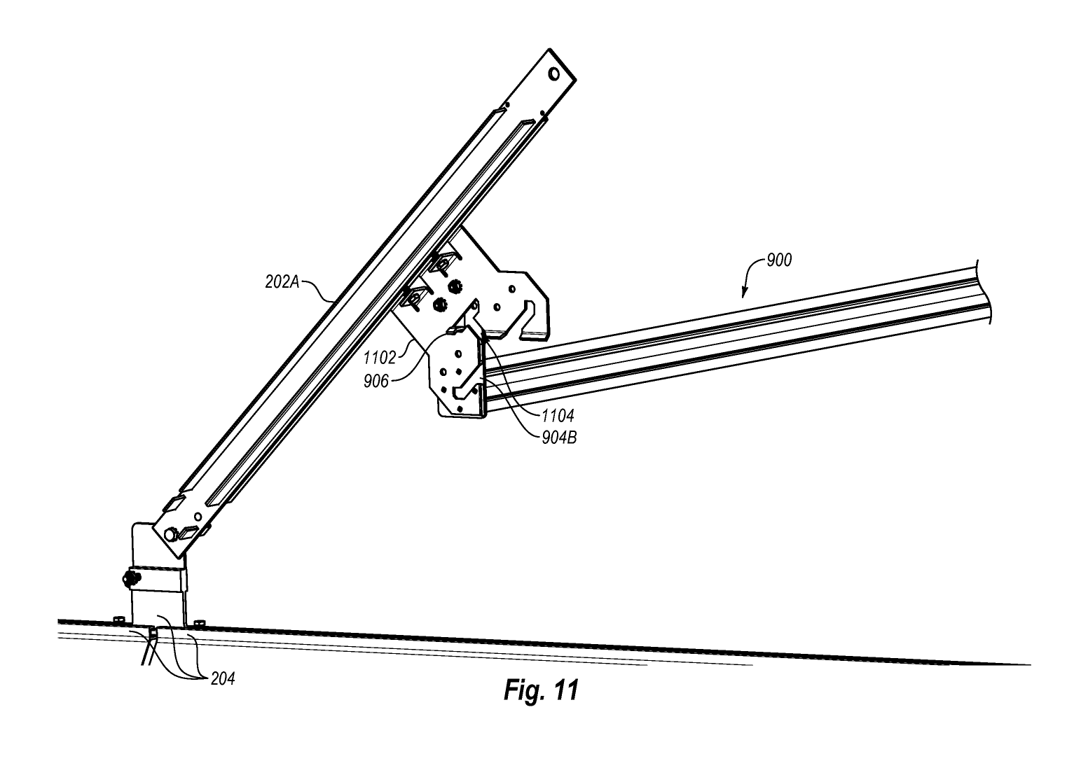

FIG. 11 is a perspective view of a portion of the PV system 100 of FIG. 2, arranged in accordance with at least some embodiments described herein. In particular, FIG. 11 illustrates a portion of the reflector frame 202A and a portion of the racking assembly 204.

FIG. 11 additionally illustrates a racking plate 1102 mechanically and electrically coupled to the frame 202A. The length of the elongate support 900 may be about equal to a width of the frame 202A and a second racking plate 1102 (not illustrated) may be mechanically and electrically coupled at the opposite side of the frame 202A. In this configuration, the two racking plates 1102 may be spaced apart from each other by a distance to accommodate therebetween the elongate support 900 and the two attached end plates 904 with each of the end plates 904 being in direct physical contact with a corresponding one of the two racking plates 1102.

Each of the racking plates 1102 may define a slot 1104. Each slot 1104 may be configured to receive therein the tongue 906 of the corresponding end plate 904 to at least temporarily secure the elongate support 900 and the attached inverter units 106 to the frame 202 during installation. The racking plates 1102 and the end plates 904 may thereby suspend the elongate support 900 and the attached inverter units 106 beneath the frame 202A near a final installation location of the elongate support 900 and the attached inverter units 106. With the elongate support 900 and the attached inverter units 106 suspended in the approximate final installation location beneath the frame 202A, an installer can adjust the positioning of the elongate support 900 and the attached inverter units 106, as needed, and then permanently or semi-permanently mechanically couple each end plate 904 to the corresponding racking plate 1102 using one or more threaded fasteners, pins, clips, adhesive, or other suitable fasteners.

The implementations described herein may include the use of a special purpose or general purpose computer including various computer hardware or software modules, as discussed in greater detail below.

Implementations described herein may be implemented using computer-readable media for carrying or having computer-executable instructions or data structures stored thereon. Such computer-readable media may be any available media that may be accessed by a general purpose or special purpose computer. By way of example, and not limitation, such computer-readable media may include non-transitory computer-readable storage media including RAM, ROM, EEPROM, CD-ROM or other optical disk storage, magnetic disk storage or other magnetic storage devices, or any other storage medium which may be used to carry or store desired program code in the form of computer-executable instructions or data structures and which may be accessed by a general purpose or special purpose computer. Combinations of the above may also be included within the scope of computer-readable media.

Computer-executable instructions comprise, for example, instructions and data which cause a general purpose computer, special purpose computer, or special purpose processing device to perform a certain function or group of functions. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

As used herein, the term “module” or “component” may refer to software objects or routines that execute on the computing system. The different components, modules, engines, and services described herein may be implemented as objects or processes that execute on the computing system (e.g., as separate threads). While the system and methods described herein are preferably implemented in software, implementations in hardware or a combination of software and hardware are also possible and contemplated. In this description, a “computing entity” may be any computing system as previously defined herein, or any module or combination of modulates running on a computing system.

The present invention may be embodied in other specific forms without departing from its spirit or essential characteristics. The described embodiments are to be considered in all respects only as illustrative and not restrictive. Unless context dictates otherwise, the various embodiments are not mutually exclusive with each other and may be combined in any desired combination. The scope of the invention is, therefore, indicated by the appended claims rather than by the foregoing description. All changes which come within the meaning and range of equivalency of the claims are to be embraced within their scope.

What is claimed is:

1. A photovoltaic system comprising:
a direct current (DC) bus;
a plurality of photovoltaic modules electrically coupled in parallel to the DC bus, wherein:
each of the photovoltaic modules includes one or more DC-to-DC power conversion circuits;
each of the photovoltaic modules is configured to independently control a composite electrical impedance of the corresponding one or more DC-to-DC power conversion circuits to operate at maximum peak power in response to the corresponding photovoltaic module detecting that a value of a DC bus voltage on the DC bus is between a first threshold value and a second threshold value greater than the first threshold value; and
each of the photovoltaic modules is configured to independently transition from operation at maximum peak power to a constant voltage mode in response to the corresponding photovoltaic module detecting that the value of the DC bus voltage is greater than the second threshold value; and
a plurality of inverter units that have DC inputs electrically coupled in parallel to the DC bus and that have alternating current (AC) outputs electrically coupled to an AC grid, wherein:
each of the inverter units has a DC voltage setpoint that has a different value than DC voltage setpoints of at least some of the other inverter units;
each of the inverter units is configured to independently begin converting DC power on the DC bus to AC power output to the AC grid in response to the corresponding inverter unit detecting that the value of the DC bus voltage is greater than or equal to the corresponding DC voltage setpoint of the corresponding inverter unit.

2. A photovoltaic system comprising:
a direct current (DC) bus;
a plurality of photovoltaic modules electrically coupled in parallel to the DC bus; and
a plurality of inverter units that have DC inputs electrically coupled in parallel to the DC bus and that have alternating current (AC) outputs electrically coupled to an AC grid.

3. The photovoltaic system of claim 2, wherein:
each of the photovoltaic modules includes one or more DC-to-DC power conversion circuits that deliver conditioned power output to the DC bus;
the DC bus comprises two continuous elongate electrical conductors, each having a cross-sectional area of at least 33 millimeters squared (mm²); and
each of the photovoltaic modules includes two self-tapping bus connectors that electrically couple the photovoltaic module to the DC bus, each of the self-tapping bus connectors having a cross-sectional area of at least 33 mm².

4. The photovoltaic system of claim 2, wherein:
each inverter unit has a DC voltage setpoint; and
each inverter unit is configured to pull DC power from the DC bus in response to the corresponding inverter unit detecting that the DC bus voltage on the DC bus is greater than or equal to the corresponding DC voltage setpoint, all without considering total DC power on the DC bus or whether other inverter units are pulling DC power from the DC bus.

5. The photovoltaic system of claim 2, wherein:
each of the inverter units has a DC voltage setpoint that has a different value than DC voltage setpoints of at least some of the other inverter units; and
an amount of power converted by each of the inverter units from DC power to AC power depends on total DC power on the DC bus and DC voltage setpoints of all the other inverter units.

6. The photovoltaic system of claim 2, wherein
at least one of the photovoltaic modules includes one or more DC-to-DC power conversion circuits;
each of the at least one of the photovoltaic modules is configured to independently control a composite electrical impedance of the corresponding one or more DC-to-DC power conversion circuits to operate at maximum peak power in response to the corresponding photovoltaic module detecting that a value of a DC bus voltage on the DC bus is between a first threshold value and a second threshold value greater than the first threshold value; and
each of the at least one of the photovoltaic modules is configured to independently transition from operation at maximum peak power to a constant voltage mode in response to the corresponding photovoltaic module detecting that the value of the DC bus voltage is greater than the second threshold value.

7. The photovoltaic system of claim 6, wherein:
a DC capacity of the photovoltaic modules is about two times greater than an AC capacity of the inverter units; and
a size of the DC bus is smaller than and not matched to the DC capacity.

8. The photovoltaic system of claim 2, wherein:
the photovoltaic system is configured to operate during sequential operation periods during each of which the photovoltaic system produces power and between which the photovoltaic system does not produce power;
each of the inverter units has a DC voltage setpoint that is changed from operation period to operation period such that, for each inverter unit, the corresponding DC voltage setpoint has a different value during a first one of the operation periods than during a second subsequent one of the operation periods; and
during each of the operation periods, the DC voltage setpoint of each of the inverter units has a different value than DC voltage setpoints of at least some of the other inverter units.

9. The photovoltaic system of claim 2, further comprising a plurality of overcurrent protection devices coupled between the inverter units and the DC bus, wherein a different one of the overcurrent protection devices is coupled between the DC bus and each corresponding inverter unit.

10. The photovoltaic system of claim 2, wherein:
each inverter unit has a DC voltage setpoint;
the photovoltaic system does not include a central control device that coordinates or controls operation of the inverter units; and
a flow of energy from the DC bus to the AC grid is controlled by each of the inverter units independently responding to a difference between a DC bus voltage of the DC bus and the corresponding DC voltage setpoint.

11. The photovoltaic system of claim 2, wherein:
each inverter unit has a DC voltage setpoint; and
each inverter unit has a finite slope of DC voltage setpoint versus power on the DC bus such that as power on the DC bus increases, the corresponding DC voltage setpoint of each inverter unit increases.

12. The photovoltaic system of claim 2, wherein:
the photovoltaic modules are configured to determine capacitance available to the photovoltaic system at startup and impedance across a power range; and
the photovoltaic modules are configured to adjust a maximum rate of power change on the DC bus to match output capacity of the photovoltaic modules to inverter capacity of the inverter units.

13. The photovoltaic system of claim 2, wherein:
each of the inverter units has a DC voltage setpoint that has a different value than DC voltage setpoints of at least some of the other inverter units; and
values of the DC voltage setpoints are asymmetrically distributed across the inverter units such that:
one or more first values of the DC voltage setpoints are each associated with a different single one of the inverter units; and
one or more second values of the DC voltage setpoints that are each higher than the one or more first values are each associated with different sets of two or more of the inverter units.

14. The photovoltaic system of claim 2, further comprising a central control device communicatively coupled to the inverter units and that is configured to coordinate and/or control operation of the inverter units.

15. The photovoltaic system of claim 14, wherein:
each inverter unit is configured to turn on or off responsive to an enable signal or a disable signal received from the central control device; and
communication between the central control device and the inverter units is one-way and solely from the central control device to the inverter units and does not include a handshake or other communication from any of the inverter units to the central control device to confirm a response to the enable signal or disable signal received from the central control device.

16. The photovoltaic system of claim 14, wherein:
the inverter units are divided into groups, each group having a different group number that identifies the corresponding group;
each inverter unit has an identification number that uniquely identifies the inverter unit within a corresponding group, the group number and identification number of each inverter unit collectively uniquely identifying the corresponding inverter unit within the photovoltaic system;
the central control device is further configured to broadcast one or more group numbers responsive to a determination that turning off the inverter units included in one or more groups corresponding to the one or more group numbers will improve efficiency of the photovoltaic system;
each inverter unit is configured to turn off responsive to receiving a broadcast from the central control device that includes the group number of the corresponding inverter unit; and
communication between the central control device and the inverter units does not include a handshake or other communication from any of the inverter units to the central control device to confirm a response to the broadcast.

17. The photovoltaic system of claim 16, wherein each inverter unit that turns off responsive to receiving the broadcast that includes the group number of the corresponding inverter unit is configured to turn on and resume operation after passage of a pre-programmed duration of time and without receiving a communication from the central control device to turn on and resume operation.

18. The photovoltaic system of claim 14, wherein:
an energy storage device is electrically coupled to the DC bus;
each of the inverter units has a DC voltage setpoint with a value that is less than a lower charge threshold value of the energy storage device; and
each of the inverter units is configured to export power from the energy storage device via the DC bus to the AC grid responsive to an enable signal from the central control device and responsive to a voltage of the energy storage device being greater than or equal to the corresponding DC voltage setpoint of the corresponding inverter unit.

19. The photovoltaic system of claim 14, wherein at least one of:
the AC grid comprises a three-phase AC grid; a first set of one or more of the inverter units is electrically coupled to a first phase of the AC grid; a second set of one or more of the inverter units is electrically coupled to a second phase of the AC grid; a third set of one or more of the inverter units is electrically coupled to a third phase of the AC grid; and the central control device is further configured to selectively enable or disable each of the first set, the second set, and the third set to phase balance; and
a fourth set of one or more of the inverter units has first reactive power (VAR) settings; a fifth set of one or more of the inverter units has second VAR settings that are different than the first VAR settings; and the central control device is further configured to selectively enable or disable each of the fourth set and the fifth set to adjust VAR of the photovoltaic system.

20. The photovoltaic system of claim 14, further comprising a plurality of failover inverter units that have DC inputs electrically coupled in parallel to the DC bus and that have AC outputs electrically coupled to the AC grid, wherein:
the failover inverter units are semi-permanently disabled;
the central control device is configured to detect failed inverter units; and
the central control device is configured to enable failover inverter units responsive to detecting the failed inverter units.

21. The photovoltaic system of claim 14, wherein:
the central control device is further configured to at least one of: set DC voltage setpoints of the inverter units and to enable and/or disable operation of the inverter units; and
the central control device is further configured to communicate with the inverter units through at least one of power line carrier communication or radio frequency (RF) communication to communicate DC voltage setpoints, enable signals, and/or disable signals to the inverter units.

22. The photovoltaic system of claim 2, wherein:
the inverter units are communicatively coupled together;
the inverter units are configured to communicate with each other to coordinate assignment of DC voltage setpoints to each of the inverter units; and
the inverter units are further configured to communicate with each other through at least one of power line carrier communication or radio frequency (RF) communication.

23. The photovoltaic system of claim 22, wherein the inverter units are assigned DC voltage setpoints at least once daily based on at least one of:
total power-on time of each inverter unit;
a cumulative sum for each inverter unit across multiple temperature ranges of power-on time of the corresponding inverter unit while operating at a corresponding one of the temperature ranges multiplied by a temperature within the corresponding one of the temperature ranges;
self-monitored efficiency of each inverter unit;
current temperature of each inverter unit; and
AC voltage output of each inverter unit.

24. The photovoltaic system of claim 2, wherein:
at least one of:
the photovoltaic system further includes a central control device communicatively coupled to the inverter units and that is configured to coordinate and/or control operation of the inverter units; and
the inverter units are configured to communicate with each other to coordinate assignment of DC voltage setpoints to each of the inverter units; and
responsive to failure of the central control device, failure of communication with the central control device, or failure of communication with each other, each of the inverter units is configured to at least one of:
independently set a DC voltage setpoint of the corresponding inverter unit; and
operate independently of the other inverter units based on a DC bus voltage on the DC bus and based on the DC voltage setpoint of the corresponding invert unit.

25. The photovoltaic system of claim 24, wherein a DC voltage setpoint of each of the inverter units is configured to be adjusted based on temperature of the corresponding inverter unit, including:
increasing a value of the DC voltage setpoint of the corresponding inverter unit responsive to a temperature of the corresponding inverter unit increasing by a threshold amount or being at or above a first temperature threshold value; and
decreasing the value of the DC voltage setpoint of the corresponding inverter unit responsive to the temperature of the corresponding inverter unit decreasing by the threshold amount or being at or below a second temperature threshold value that is lower than the first temperature threshold value.

26. The photovoltaic system of claim 2, wherein:
a first set of one or more of the inverter units have peak efficiency in a first power range;
a second set of one or more of the inverter units have peak efficiency in a second power range;
a minimum value of the second power range is greater than a maximum value of the first power range; and
a DC voltage setpoint of each inverter unit in the first set has a lower value than a DC voltage setpoint of each inverter unit in the second set.

27. The photovoltaic system of claim 2, further comprising a common housing unit and a common printed circuit board (PCB) backplane included within the common housing unit, wherein:
each of the inverter units is contained in a different PCB card installed within the common housing unit;
the inverter units are electrically coupled in parallel to the DC bus through the PCB backplane; and
the PCB backplane includes a common AC output bus electrically coupled to the AC grid and through which the inverter units are electrically coupled to the AC grid.

28. The photovoltaic system of claim 27, wherein the PCB backplane includes at least one common component shared between two or more of the inverter units.

29. The photovoltaic system of claim 2, wherein each of the inverter units is configured to curtail AC power output responsive to a temperature of the corresponding inverter unit reaching a temperature threshold value.

30. The photovoltaic system of claim 2, further comprising an energy storage device electrically coupled in parallel with the photovoltaic modules to the DC bus.

31. The photovoltaic system of claim 30, wherein:
each of the inverter units is configured for binary operation including on at a single power level or off;
each of the inverter units is configured to operate at a voltage range that is less than or equal to an operating voltage range of the photovoltaic system; and
the operating voltage range includes a range from a lower charge threshold value to an upper charge threshold value of the energy storage device;

32. The photovoltaic system of claim 30, wherein each inverter unit is configured to limit its output power while operating and in response to a power limiting command that indicates a target output power level.

33. The photovoltaic system of claim 2, wherein the inverter units comprise first inverter units, the photovoltaic system further comprising one or more auxiliary inverter units that have DC inputs electrically coupled in parallel with DC inputs of the first inverter units and that have AC outputs electrically coupled to an auxiliary AC circuit that is isolated from the AC grid.

34. The photovoltaic system of claim 33, wherein:
each of the one or more auxiliary inverter units has a DC voltage setpoint with a value that is lower than any DC voltage setpoint values of the first inverter units such that energy is delivered to the auxiliary AC circuit before energy is delivered to the AC grid; or
each of the one or more auxiliary inverter units has a DC voltage setpoint with a value that is higher than any DC voltage setpoint values of the first inverter units such that energy is delivered to the AC grid before energy is delivered to the auxiliary AC circuit.

35. The photovoltaic system of claim 33, further comprising an energy storage device coupled to the DC bus and configured to support inrush current requirements of loads electrically coupled to the auxiliary AC circuit.

36. The photovoltaic system of claim 33, further comprising an energy storage device electrically coupled in parallel with the photovoltaic modules to the DC bus.

37. The photovoltaic system of claim 2, further comprising an AC-to-DC converter connected between the AC grid and the DC bus and configured to convert AC energy from the AC grid to DC energy on the DC bus to at least one of:
recharge an energy storage device coupled to the DC bus; and
power one or more auxiliary inverter units that have DC inputs electrically coupled in parallel with DC inputs of the first inverter units and that have AC outputs electrically coupled to an auxiliary AC circuit that is isolated from the AC grid.

38. The photovoltaic system of claim 2, further comprising an elongate support to which each of the inverter units is attached.

39. The photovoltaic system of claim 38, further comprising a plurality of reflectors, wherein:
the elongate support and the inverter units are mounted to the photovoltaic system behind at least one of the reflectors; and
the reflectors are configured to reflect at least some illumination incident on the reflectors onto the photovoltaic modules such that the reflected light is not incident on the elongate support and the inverter units.

40. The photovoltaic system of claim 38, wherein:
the elongate support comprises an extruded rod;
the elongate support includes extruded semi-cylindrical slots formed in the extruded rod that extend in a direction parallel to a length of the elongate support;
the photovoltaic system further comprises two end plates mechanically coupled to opposite ends of the extruded rod by at least one screw at each of the opposite ends, the at least one screw being threadably received in at least one of the extruded semi-cylindrical slots at the corresponding one of the opposite ends; and
the two end plates are configured to mechanically couple the extruded rod with the attached inverter units to the photovoltaic system.

41. The photovoltaic system of claim 39, further comprising:
two end plates mechanically coupled to opposite ends of the elongate support; and
two racking plates mechanically coupled to a frame that supports the at least one of the reflectors and/or other elements of the photovoltaic system, wherein:
the two racking plates are spaced apart from each other by a distance to accommodate therebetween the elongate support and the two end plates with each of the two end plates in direct physical contact with a corresponding one of the two racking plates;
each of the two end plates comprises a tongue that extends away from the elongate support; and
each of the two racking plates defines a slot configured to receive therein the tongue of the corresponding one of the two end plates to at least temporarily secure the elongate support and the inverter units to the frame during installation.
